(19) United States
(12) Patent Application Publication
(10) Pub. No.: US 2026/0271418 A1
(43) Pub. Date: Sep. 10, 2026

(54) IMAGE SENSOR INCLUDING NON-FILTER PIXEL AND METHOD OF MANUFACTURING THE SAME

(71) Applicant: Samsung Electronics Co., Ltd., Suwon-si (KR)

(72) Inventors: Taesung Lee, Suwon-si (KR); Dongjin Kim, Suwon-si (KR); Hyeyeon Park, Suwon-si (KR); Mingyu Bae, Suwon-si (KR); Huiwon Yun, Suwon-si (KR); Hyeongseop Im, Suwon-si (KR); Shinyoung Choi, Suwon-si (KR)

(73) Assignee: Samsung Electronics Co., Ltd., Suwon-si (KR)

(21) Appl. No.: 19/655,172

(22) Filed: Apr. 22, 2026

(30) Foreign Application Priority Data
Mar. 7, 2025 (KR) 10-2025-0089591

(51) Int. Cl. H10F 39/00

(52) U.S. Cl. CPC H10F 39/8053; H10F 39/024; H10F 39/8063

(57) ABSTRACT

An image sensor includes a semiconductor substrate including a plurality of pixels, an insulating film disposed on the semiconductor substrate, a plurality of color filters disposed on the insulating film, and a plurality of microlenses disposed on the plurality of color filters. The plurality of pixels include at least one non-filter pixel having no color filter disposed on the insulating film. The thickness of the color filters included in the image sensor may be measured precisely using the non-filter pixels that do not include color filters.

### CROSS-REFERENCE TO RELATED APPLICATIONS

This present application claims priority to and the benefit under 35 U.S.C. § 119(a)-(d) of Korean Patent Application No. 10-2025-0089591, filed on Jul. 3, 2025, in the Korean Intellectual Property Office, the entire disclosure of which is incorporated herein by reference.

### FIELD

Example embodiments relate generally to semiconductor integrated circuits, and more particularly to an image sensor including a non-filter pixel and a method of manufacturing the image sensor.

### BACKGROUND

Complementary metal oxide semiconductor (CMOS) image sensors are solid-state sensing devices that use complementary metal oxide semiconductors. CMOS image sensors have lower manufacturing costs and/or lower power consumption compared with charge-coupled device (CCD) image sensors. Thus, CMOS image sensors are used for various electronic appliances including portable devices such as, for example, smartphones and digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With the recent proliferation of higher-resolution images, pixels included in the CMOS image sensor are becoming much smaller. When the pixels get smaller, incident light may not be properly sensed and performance of the image sensor may be degraded.

### SUMMARY

Some example embodiments may provide an image sensor including non-filter pixels and a method of manufacturing the image sensor, capable of precisely measuring a thickness of a color filter in the image sensor.

According to example embodiments, an image sensor includes a semiconductor substrate including a plurality of pixels, an insulating film disposed on the semiconductor substrate, a plurality of color filters disposed on the insulating film, and a plurality of microlenses disposed on the plurality of color filters. The plurality of pixels include at least one non-filter pixel having no color filter disposed on the insulating film.

According to example embodiments, a method of manufacturing an image sensor, includes, providing a semiconductor substrate including a plurality of pixels, forming an insulating film on the semiconductor substrate, forming a first color filter layer on the insulating film, and patterning the first color filter layer using a first mask including a plurality of first patterns such that a color filter corresponding to at least one non-filter pixel among the plurality of pixels is not disposed to form a plurality of first color filters corresponding to the plurality of first patterns.

According to example embodiments, an image sensor includes a semiconductor substrate including a plurality of green pixels, a plurality of blue pixels, and a plurality of red pixels, an insulating film disposed on the semiconductor substrate, a plurality of green filters, a plurality of blue filters, and a plurality of red filters disposed on the insulating film, and a plurality of microlenses disposed on the plurality of green filters, the plurality of blue filters, and the plurality of red filters. The plurality of green pixels include at least one non-filter pixel having no green filter disposed on the insulating film.

The image sensor according to example embodiments may precisely measure the thickness of the color filters included in the image sensor using the non-filter pixels that do not include color filters. Through the precise thickness measurement of the color filters, the performance of the image sensor may be enhanced by the improving the manufacturing process of the image sensor and/or correcting the sensing data of the image sensor.

### BRIEF DESCRIPTION OF THE DRAWINGS

Example embodiments of the present disclosure will be more clearly understood from the following detailed description taken in conjunction with the accompanying drawings.

FIG. 1 is a plan view illustrating an image sensor according to example embodiments.

FIGS. 2 and 3 are cross-sectional views illustrating the image sensor of FIG. 1.

FIG. 4 is a block diagram illustrating an image sensor according to example embodiments.

FIG. 5 is a circuit diagram illustrating an example of a unit circuit included in an image sensor according to example embodiments.

FIG. 6 is a timing diagram illustrating an example operation of an image sensor according to example embodiments.

FIG. 7 is a diagram illustrating example embodiments of a configuration of pixels and a readout circuit according to example embodiments.

FIGS. 8 to 32 are diagrams for describing a method of manufacturing an image sensor and a thickness measurement according to example embodiments.

FIG. 33 is a plan view illustrating an image sensor according to example embodiments.

FIGS. 34 to 36 are diagrams illustrating examples of arrangement of non-filter pixels included in an image sensor according to example embodiments.

FIG. 37 is a diagram illustrating a layout of a pixel array according to example embodiments.

FIGS. 38 to 47 are plan views illustrating example embodiments of a unit pixel included in the pixel array of FIG. 37.

FIG. 48 is a diagram illustrating a perspective view illustrating an image sensor according to example embodiments.

FIG. 49 is a block diagram illustrating an electronic device according to example embodiments.

FIG. 50 is a block diagram illustrating a camera module included in the electronic device of FIG. 49.

### DETAILED DESCRIPTION

Various example embodiments will be described more fully hereinafter with reference to the accompanying drawings, in which some example embodiments are shown. In the drawings, like numerals refer to like elements throughout. The repeated descriptions may be omitted.

Hereinafter, structures according to example embodiments are described using a first horizontal direction DR1, a second horizontal direction DR2, and a vertical direction DR3 in a three-dimensional space. The first horizontal direction DR1 and the second horizontal direction DR2 may be substantially parallel with an upper surface of a semiconductor substrate and substantially perpendicular to one another. The vertical direction DR3 may be substantially perpendicular to the upper surface of the semiconductor substrate. The first direction DR1 may be a row direction and the second direction DR2 may be a column direction.

Additionally, a pixel or pixel region may be represented as PX(Ci), where C represents a color or a color filter corresponding to the pixel, and i may be an index for distinguishing the color filter C.

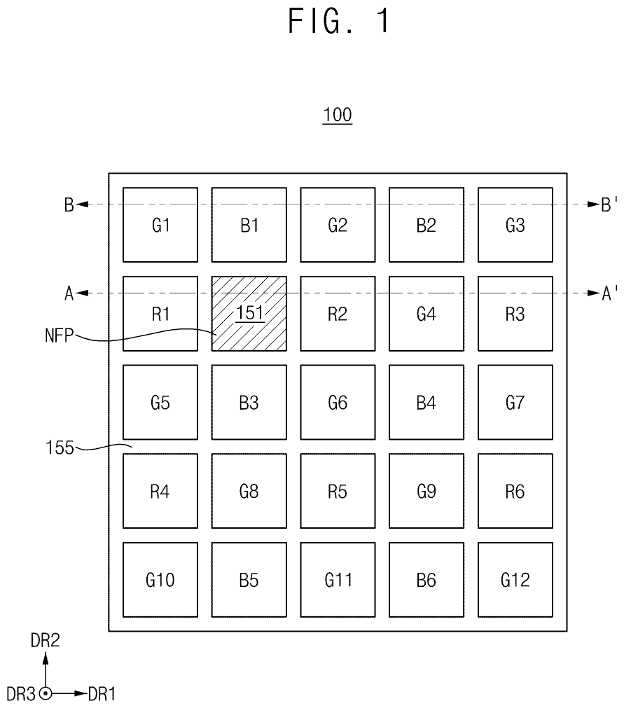

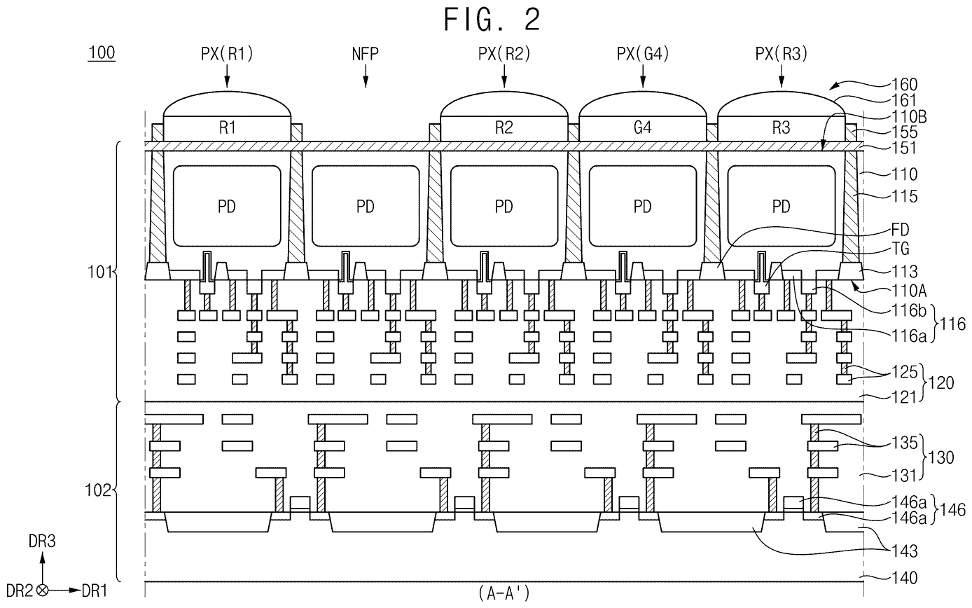

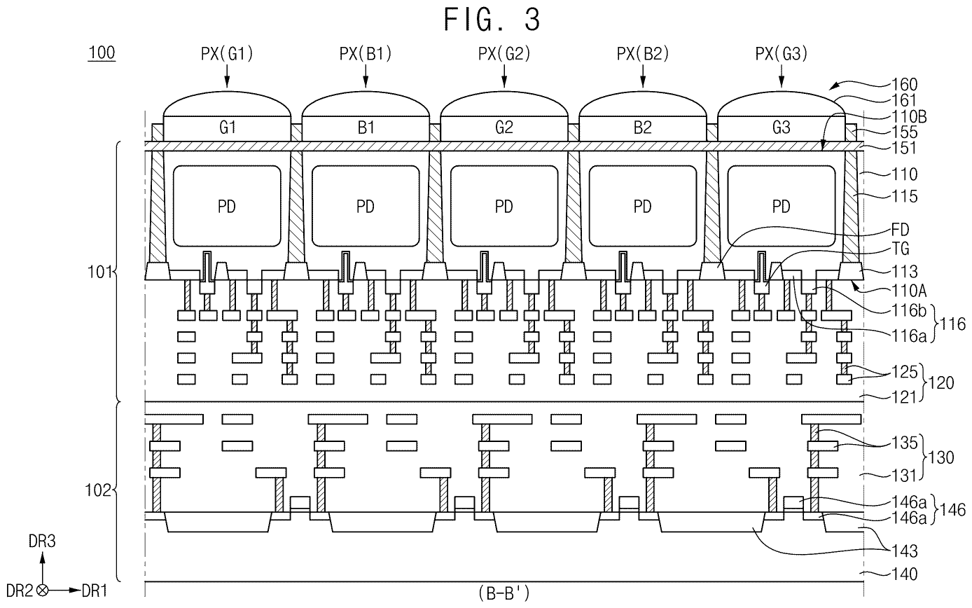

FIG. 1 is a plan view illustrating an image sensor according to example embodiments, and FIGS. 2 and 3 are cross-sectional views illustrating the image sensor of FIG. 1. FIG. 2 is a vertical cross-sectional view taken along a line A-A′ of FIG. 1, and FIG. 3 is a vertical cross-sectional view taken along a line B-B′ of FIG. 1.

Referring to FIGS. 1 to 3, an image sensor 100 according to example embodiments includes a second semiconductor chip 102 and a first semiconductor chip 101 disposed on the second semiconductor chip 102. The first semiconductor chip 101 may include a first semiconductor substrate 110 including a plurality of pixels (or pixel regions) PX arranged in a matrix structure. In the example embodiments of FIGS. 1 to 3, a case in which the plurality of pixel regions PX are arranged in five rows and five columns is described as an example, but is not limited thereto, and the number of rows and the number of columns of the plurality of pixel regions PX may be variously modified. In addition, the image sensor 100 may be an RGB image sensor including red pixels PX(R1) to PX(R6, green pixels PX(G1) to PX(G12), and blue pixels PX(B1) to PX(B6), but the color filter array of the image sensor 100 is not limited thereto. Each of the plurality of pixel regions PX may generate image data, and each of the plurality of pixel regions PX may be arranged to correspond to one micro lens 161.

The first semiconductor chip 101 may be an image sensor chip in which a plurality of pixel regions PX are arranged, and the second semiconductor chip 102 may be a logic semiconductor chip. In this disclosure, only the first semiconductor chip 101 may be referred to as an image sensor.

In example embodiments, the second semiconductor chip 102 includes a second semiconductor substrate 140 and a second wiring structure 130 disposed on the second semiconductor substrate 140. The second semiconductor substrate 140 includes a device isolation portion 143 defining an active region, and second individual devices 146 formed on the active region, and the second individual devices 146 constitute a logic circuit for image processing and may be, for example, transistor devices having impurity regions 146a provided as a source-drain and a gate structure 146b.

The second wiring structure 130 may include a second insulating layer 131 and a second multilayer wiring 135 formed within the second insulating layer 131 and connected to the second individual devices 146. The second multilayer wiring 135 may include a plurality of wiring layers positioned at different height levels and vias electrically connecting the plurality of wiring layers and/or the second individual devices 146.

The first semiconductor chip 101 includes a first semiconductor substrate 110 having a first surface 110A and a second surface 110B positioned opposite to one another. A first wiring structure 120 may be disposed on the first surface 110A of the first semiconductor substrate 110. The first semiconductor substrate 110 may include a device isolation pattern 115 defining pixel regions PX and photoelectric conversion elements PD disposed in each pixel region PX. For example, the photoelectric conversion elements PD may generate and accumulate charges in proportion to the amount of light incident from the second surface 110B of the first semiconductor substrate 110. The first photoelectric conversion elements PD may be formed within the first semiconductor substrate 110. The first semiconductor substrate 110 may include, together with the photoelectric conversion elements PD, a device isolation portion 113 disposed on the first surface 110A and defining an active area, a transfer gate TG and a floating diffusion region FD disposed on the active area, and a first individual gate 120 formed on the active area. The first individual elements 116 may include transistors having impurity regions 116a provided as source-drains and a gate structure 116b. These transistors may include a reset transistor, a selection transistor, and a source follower transistor. The first wiring structure 120 may include a first insulating layer 121 and a first multilayer wiring 125 formed within the first insulating layer 121 and connected to the first individual elements 116. The image sensor 100 may include an insulating film 151, color filters R1 to R6, G1 to G12, and B1 to B6, and a microlens layer 160 sequentially arranged on the second surface 110B of the first semiconductor substrate 110. The insulating film 151 may be formed between the second surface 110B of the semiconductor substrate 110 and the color filters R1 to R6, G1 to G12, and B1 to B6 to cover the second surface 110B. The insulating film 151 may include an anti-reflection film.

A light-shielding pattern 155 may be disposed on the insulating film 151 to define pixel regions PX. The light-shielding pattern 155 may define spaces for arranging the color filters R1 to R6, G1 to G12, and B1 to B6. The light-shielding pattern 155 may vertically overlap with the device isolation pattern 115. The light-shielding pattern 155 may not vertically overlap with the photoelectric conversion element PD within the pixel regions PX. For example, the light-shielding pattern 155 may include a metal such as tungsten.

The color filters R1 to R6, G1 to G12, and B1 to B6 may be respectively arranged in spaces defined by the light-shielding pattern 155 to provide the pixel regions PX for image sensing. In example embodiments, the color filters R1 to R6, G1 to G12, and B1 to B6 may include green filters G1 to G12, blue filters B1 to B6, and red filters R1 to R6. In example embodiments, the color filters R1 to R6, G1 to G12, and B1 to B6 may each vertically overlap one photoelectric conversion element PD arranged in one pixel region PX. The color filters R1 to R6, G1 to G12, and B1 to B6 may transmit light of different specific wavelengths and generate charges from the light of the specific wavelength in the photoelectric conversion element PD located therebelow. As illustrated in FIG. 1, the color filters R1 to R6, G1 to G12, and B1 to B6 may be arranged in a Bayer pattern. Example

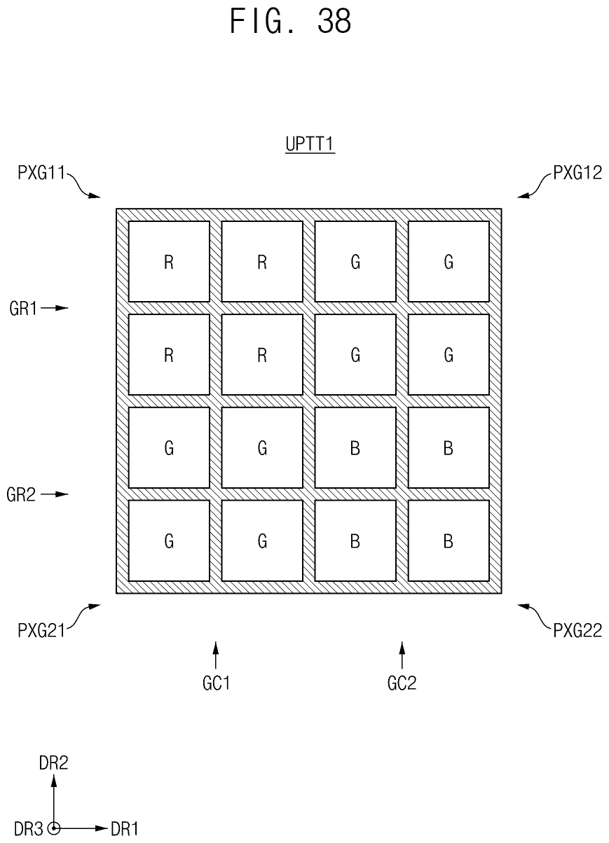

embodiments are not limited to a specific arrangement pattern of color filters, and color filters or color pixels included in an image sensor according to example embodiments may have various arrangement patterns as will be described below with reference to FIGS. 38 to 47.

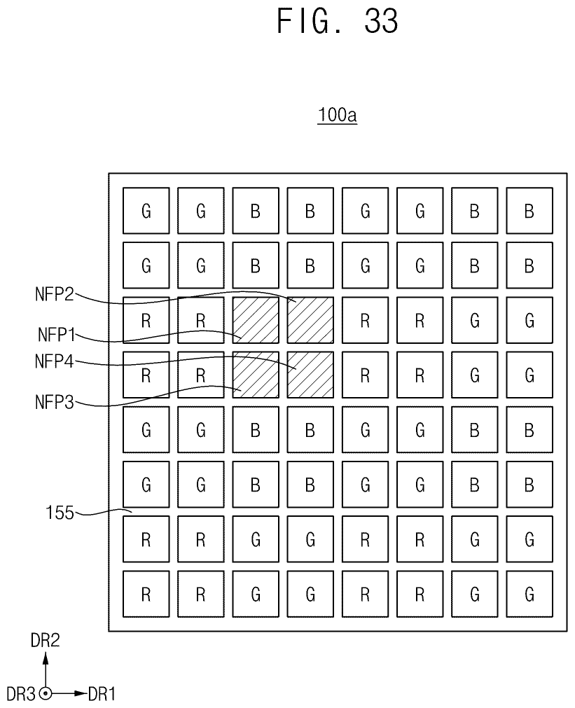

As illustrated in FIGS. 1 and 2, the plurality of pixels PX included in the image sensor 100 according to example embodiments may include at least one non-filter pixel NFP in which a color filter is not arranged on an insulating film 151. Although one non-filter pixel NFP is illustrated in FIGS. 1 to 3, the number and position of non-filter pixels included in the image sensor may be determined in various ways as will be described below with reference to FIGS. 33 to 36.

As described above, a plurality of pixels included in the image sensor 100 may include red pixels PX(R1) to PX(R6) having red filters R1 to R6 disposed thereon, green pixels PX(G1) to PX(G12) having green filters G1 to G12 disposed thereon, and blue pixels PX(B1) to PX(B6) having blue filters B1 to B6 disposed thereon. In this case, a non-filter pixel NFP may correspond to a pixel from which the green filter is omitted.

According to example embodiments, the color of the omitted color filter of the non-filter pixel NFP may be determined in various ways. In example embodiments, the non-filter pixel NFP may correspond to the color of the largest number of color filters in the image sensor. In example embodiments, the color filters may be sequentially formed for each color, and the non-filter pixel NFP may correspond to the color of the color filters that are formed first.

In example embodiments, as illustrated in FIG. 2, a microlens may not be positioned in the non-filter pixel NFP. When a color filter and microlens are not arranged in a non-filter pixel NFP, the non-filter pixel NFP has a significant step difference from other pixels. This step difference may be detected during the manufacturing and testing processes to identify the location of the non-filter pixel NFP. By identifying the location of the non-filter pixel NFP, the non-filter pixel NFP may be used as a pixel count marker to identify the locations of the plurality of pixels included in the image sensor.

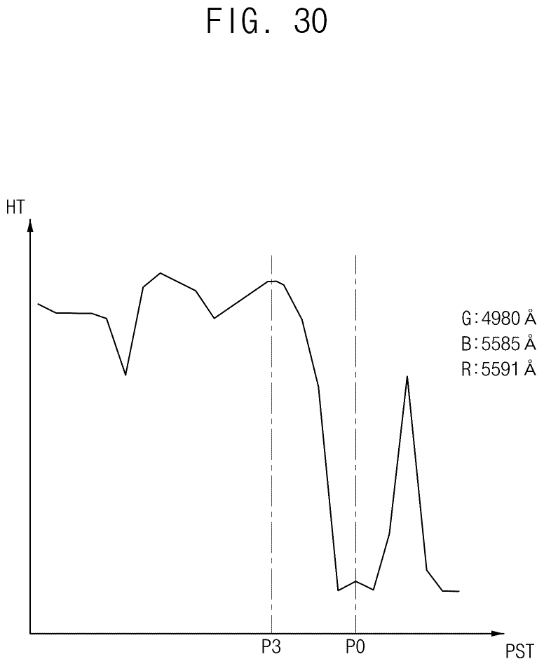

In example embodiments, as will be described below with reference to FIG. 30, the surface of the insulating film 151 corresponding to the non-filter pixel NFP may be used as a reference surface for measuring the thickness of the color filters.

If color filters are arranged in all pixels, the thickness of the color filters that are formed last may be estimated based on the step difference from other color filters, and the accuracy of the thickness measurement may be degraded. For example, when green filters, blue filters, and red filters are sequentially formed, the thickness of the last red filter has to be estimated based on the step difference with the green filters and/or the blue filter. In addition, even if the thickness of the green filter and the thickness of the blue filter are measured before forming the red filters, the thickness of the green filter and the thickness of the blue filter may change during the process of forming the red filters. In this case, the thickness of the green filter and the thickness of the blue filter cannot be accurately determined.

On the other hand, the image sensor according to example embodiments may accurately measure the thickness of all color pixels by using the surface of the insulating film 151 corresponding to the non-filter pixel NFP as a reference surface for measuring the thickness of the color filters.

As such, the image sensor according to example embodiments may precisely measure the thickness of the color filters included in the image sensor using the non-filter pixels that do not include color filters. Through the precise thickness measurement of the color filters, the performance of the image sensor may be enhanced by the improving the manufacturing process of the image sensor and/or correcting the sensing data of the image sensor.

FIG. 4 is a block diagram illustrating an image sensor according to example embodiments.

Referring to FIG. 4, an image sensor 600 may include a pixel array 620, a row driver 630, an analog-to-digital conversion circuit 640, a column driver 650, a controller 660, and/or a reference signal generator (REF) 670.

The pixel array 620 includes a plurality of pixels 700 coupled to column lines COL, respectively. For example, each of the plurality of pixels 700 may be coupled to a respective column line COL. The plurality of pixels 700 are configured to sense incident light to generate analog signals through the column lines COL. The plurality of pixels 700 may be arranged in matrix form with a plurality of rows and a plurality of columns. The pixel array 620 may have a structure in which a plurality of unit patterns are arranged repeatedly in a first horizontal direction and a second horizontal direction that is perpendicular to the first horizontal direction.

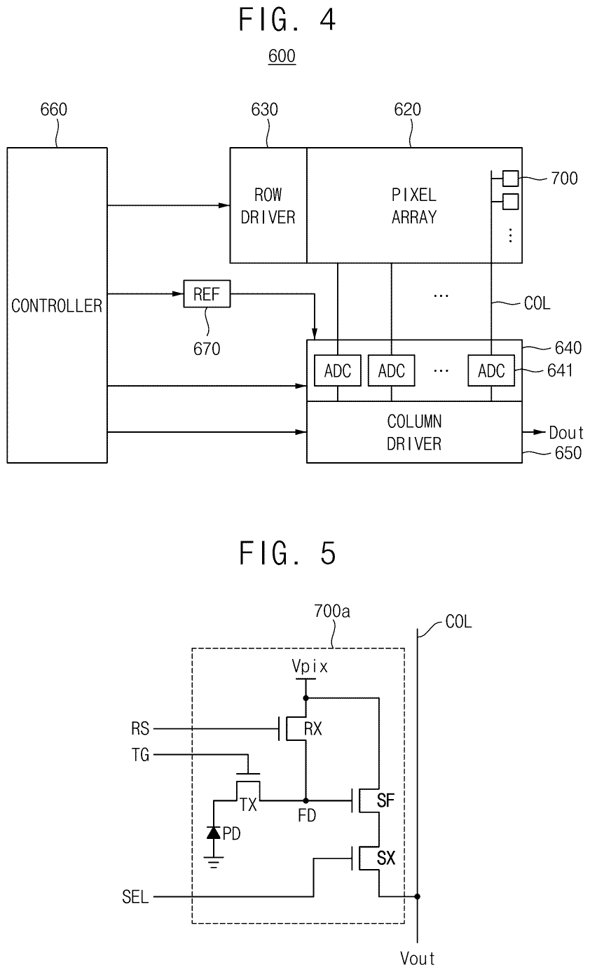

The row driver 630 may be coupled to the rows of the pixel array 620 and may be configured to generate signals for driving the rows. For example, the row driver 630 may drive (e.g., control or select) the pixels in the pixel array 620 row by row. For example, the row driver 630 may control the pixels in the pixel array 620 row by row such that one of rows included in the pixel array 20 is selected by providing an activated row selection signal SEL to the selected row of the pixel array 620 as described below with reference to FIGS. 5A, 5B, and 5C.

The analog-to-digital conversion circuit 640 may be coupled to the columns of the pixel array 620 and may be configured to convert the analog signals from the pixel array 20 to digital signals. As illustrated in FIG. 5A, the analog-to-digital conversion circuit 640 may include a plurality of analog-to-digital converters (ADC) 641 to perform analog-to-digital conversion of the analog signals output from the column lines COL in parallel or simultaneously.

The analog-to-digital conversion circuit 640 may include a correlated double sampling (CDS) unit. In some example embodiments, the CDS unit may perform an analog double sampling by extracting a valid image component based on a difference between an analog reset signal and an analog image signal. In some example embodiments, the CDS unit may perform a digital double sampling by converting the analog reset signal and the analog image signal to two digital signals and extracting a difference between the two digital signals as the valid image component. In some example embodiments, the CDS unit may perform a dual CDS by performing both the analog double sampling and digital double sampling.

The column driver 650 may be configured to output the digital signals from the analog-to-digital conversion circuit 40 sequentially as output data Dout.

The controller 660 may be configured to control the row driver 30, the analog-to-digital conversion circuit 640, the column driver 650, and/or the reference signal generator 670. The controller 660 may provide control signals such as clock signals, timing control signals, etc. applied to the operations of the row driver 630, the analog-to-digital conversion circuit 640, the column driver 650, and/or the reference signal generator 670. The controller 660 may include a control logic circuit, a phase-locked loop, a timing control circuit, a communication interface circuit, etc. In example embodiments, the controller 660 and the pixel array 620 may be embodied as a single semiconductor chip. In example embodiments, the controller 660 and the pixel array 620 may each be embodied as separate semiconductor chips and electrically connected to one another.

The reference signal generator 670 may generate a reference signal or a ramp signal that increases or decreases gradually (e.g., with a slope), and provide the ramp signal to the analog-to-digital conversion circuit 40.

FIG. 5 is a circuit diagram illustrating an example of a unit circuit included in an image sensor according to example embodiments.

Referring to FIG. 5, a unit pixel 700a may include a photo-sensitive element such as a photodiode PD, and a readout circuit including a transfer transistor TX, a reset transistor RX, a source follower transistor SF, and/or a selection transistor SX.

The photo-charges generated in the photodiode PD may be transferred to a floating diffusion node FD through the transfer transistor TX. For example, the transfer transistor TX may be turned on in response to a transfer control signal TG, when the transfer control signal TG has a first level (e.g., a logic high level), and the photocharges generated in the photodiode PD may be transferred to the floating diffusion region FD through the turned-on transfer transistor TX.

The source follower transistor SF is configured to function as a source follower amplifier that amplifies a signal corresponding to the charge on the floating diffusion node FD. The selection transistor SX may transfer the pixel signal Vpix to a column line COL in response to a selection signal SEL.

The floating diffusion node FD may be configured to be reset by the reset transistor RX. For example, the reset transistor RX may discharge the floating diffusion node FD in response to a reset signal RS for correlated double sampling (CDS).

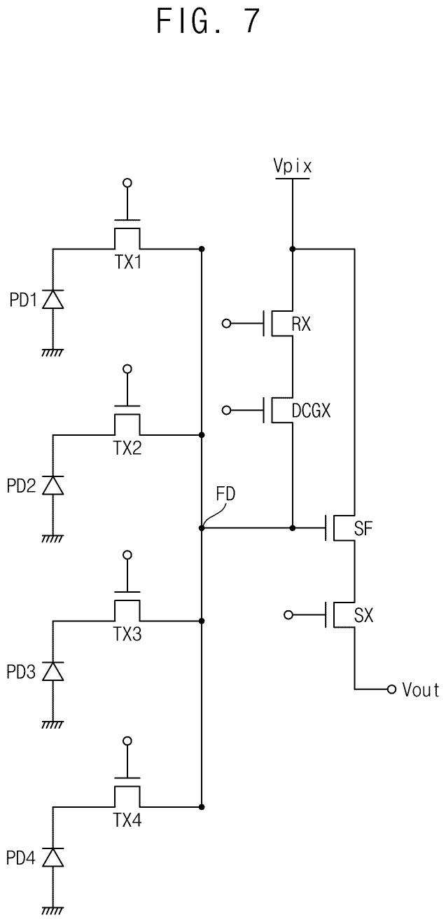

The reset transistor RX, the source follower transistor SF, and the selection transistor SX may be distributed in a plurality of pixels or sub-pixels, as will be described below with reference to FIG. 7. The pixel transistor PXT described above may correspond to the reset transistor RX, the source follower transistor SF, or the selection transistor SX.

FIG. 5 illustrates the unit pixel 700a of the four-transistor configuration including the four transistors TX, RX, SF, and SX. The configuration of the unit pixel may be variously changed, and the pixel structure is not limited to that of FIG. 5. In embodiments, additional transistors may be included in the unit circuit to implement multiple conversion gains as will be described below with reference to FIG. 7.

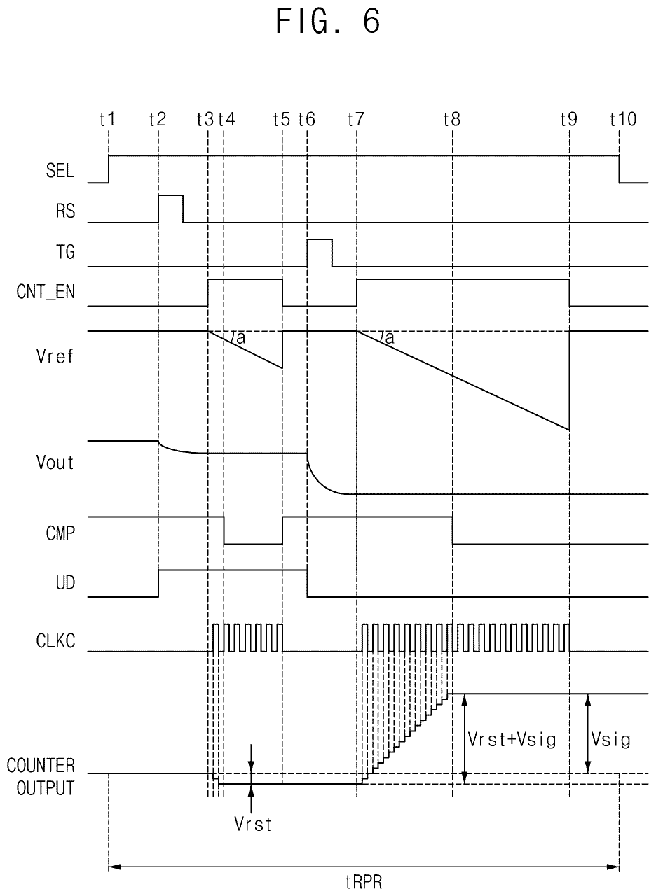

FIG. 6 is a timing diagram illustrating an example operation of an image sensor according to example embodiments.

FIG. 6 illustrates a sensing period tRPR corresponding to a sensing operation of a pixel. The sensing operation may be performed simultaneously with respect to pixels corresponding to the same transfer control signal TG.

Referring to FIGS. 4, 5, and 6, at a time t1, the row driver 630 may select one of rows included in the pixel array 20 by providing an activated row selection signal SEL to the selected row of the pixel array 620.

At a time t2, the row driver 630 may provide an activated reset control signal RS to the selected row, and the controller 60 may provide an up-down control signal UD having a logic high level to a counter included in the ADC 641. From the time t2, the pixel array 620 may output a first analog signal corresponding to a reset component Vrst as the pixel power voltage Vpix.

At a time t3, the controller 660 may provide a count enable signal CNT_EN having a logic high level to the reference signal generator 670, and the reference signal generator 670 may start to decrease the reference signal Vref at the constant rate, e.g., a slope of ‘a’. The controller 660 may provide a count clock signal CLKC to the counter, and the counters may perform down-counting from zero in synchronization with the count clock signal CLKC.

At a time t4, a magnitude of the reference signal Vref may become smaller than a magnitude of the pixel power voltage Vpix, and a comparator included in the ADC 641 may provide a comparison signal CMP having a logic low level to the counter so that the counter stops performing the down-counting. At the time t4, a counter output of the counter may be the first counting value that corresponds to the reset component Vrst. In the example of FIG. 6, the counter output of the counter at the time t4 may be −2.

At a time t5, the controller 660 may provide the count enable signal CNT_EN having a logic low level to the reference signal generator 670, and the reference signal generator 670 may stop generating the reference signal Vref.

A period from the time t3 to the time t5 corresponds to the maximum time for detecting the reset component Vrst. A length of the period from the time t3 to the time t5 may be determined as a certain number of the count clock signal CLKC according to a characteristic of the image sensor 600.

At a time t6, the row driver 630 may provide an activated transfer control signal TG (e.g., the transfer control signal TG having a logic high level) to the selected row, and the controller 660 may provide the up-down control signal UD having a logic low level to the counter. From the time t6, the pixel array 620 may output a second analog signal AS2 corresponding to a detected incident light Vrst+Vsig as the pixel power voltage Vpix.

At a time t7, the controller 660 may provide the count enable signal CNT_EN having a logic high level to the reference signal generator 670, and the reference signal generator 670 may start to decrease the reference signal Vref at the same constant rate as at the time t3, e.g., a slope of ‘a’. The comparator may provide the comparison signal CMP having a logic high level to the counter since the pixel power voltage Vpix is smaller than the reference signal Vref. The controller 660 may provide the count clock signal CLKC to the counter, and the counter may perform an up-counting from the first counting value, which corresponds to the reset component Vrst, in synchronization with the count clock signal CLKC.

At a time t8, the magnitude of the reference signal Vref may become smaller than the magnitude of the pixel power voltage Vpix, and the comparator may provide the comparison signal CMP having a logic low level to the counter so that the counter stops performing the up-counting. At the time t8, the counter output of the counter may correspond to a difference between the first analog signal representing the reset component Vrst (e.g.,-2 in the example of FIG. 5C) and the second analog signal representing the detected incident light Vrst+Vsig (e.g., 17 in the example of FIG. 5C). The difference may be an effective intensity of incident light Vsig (e.g., 15 in the example of FIG. 5C). The counter may output the effective intensity of incident light Vsig as the digital signal.

At a time t9, the controller 660 may provide the count enable signal CNT_EN having a logic low level to the reference signal generator 670, and the reference signal generator 670 may stop generating the reference voltage Vref.

A period from the time t7 to the time t9 corresponds to the maximum time for detecting the detected incident light Vrst+Vsig. A length of the period from the time t7 to the time t9 may be determined as a certain number of the count clock signal CLKC according to a characteristic of the image sensor 600.

At a time t10, the row driver 630 may provide a deactivated row selection signal SEL (e.g., the row selection signal having a low level) to the selected row of the pixel array 620, and the counter may reset the counter output to zero.

After that, the image sensor 600 may repeat the above described operations on each row to generate the digital signals row by row.

The configuration and the sensing operation of an image sensor have been described with reference to FIGS. 5A, 5B and 5C, but example embodiments are not limited thereto.

FIG. 7 is a diagram illustrating example embodiments of a configuration of pixels and a readout circuit according to example embodiments.

FIG. 7 illustrates four sub-pixels and a readout circuit shared by the four sub-Attorney pixels. The sub-pixels may each include photoelectric conversion regions PD1, PD2, PD3, and PD4 and transfer transistors TX1, TX2, TX3, and TX4. The readout circuit may include a reset transistor RX, a selection transistor SX, a source follower transistor SF, and a double conversion gain transistor DCG. The reset transistor RX may include a reset gate RG, the selection transistor SX may include a selection gate SEL, the source follower transistor SF may include a source follower gate SFG, and each of the transfer transistors TX1, TX2, TX3, and TX4 may include a transfer gate TG.

The photoelectric conversion regions PD1, PD2, PD3, and PD4 may each be connected to a floating diffusion region FD via the transfer transistors TX1, TX2, TX3, and TX4. The photoelectric conversion regions PD1, PD2, PD3, and PD4 may generate and accumulate photoelectric charges in proportion to the amount of light incident from the outside (e.g., external to the image sensor), and may be photodiodes, phototransistors, photogates, pinned photodiodes, and combinations thereof.

The transfer gate TG may transfer the photocharges generated in the photoelectric conversion regions PD1, PD2, PD3, and PD4 to the floating diffusion region FD. The floating diffusion region FD may receive and cumulatively store the charge generated by the photoelectric conversion regions PD1, PD2, PD3, and PD4. The source follower transistor SF may be controlled according to the amount of photocharges accumulated in the floating diffusion region FD.

The reset transistor RX may periodically reset the accumulated charges in the floating diffusion region FD. The drain electrode of the reset transistor RX is connected to the floating diffusion region FD and the source electrode is connected to the power supply voltage Vpix. When the reset transistor RX is turned on, the power supply voltage Vpix connected to the source electrode of the reset transistor RX is transferred to the floating diffusion region FD. When the reset transistor RX is turned on, the charge accumulated in the floating diffusion region FD may be discharged to reset the floating diffusion region FD.

The source follower transistor SF functions as a source follower buffer amplifier, amplifies the potential change in the floating diffusion region FD and outputs a current corresponding to the potential change to the output line VOUT.

The selection transistor SX may select a plurality of pixels on a row-by-row basis. When the selection transistor SX is turned on, the current generated by the source follower transistor SF may be transferred to the output line VOUT.

The dual conversion gain transistor DCG may adjust the conversion gain. For example, the conversion gain may be adjusted by applying a dual gain signal having a logic high level or a dual gain signal having a logic low level to the gate of the dual conversion gain transistor DCG.

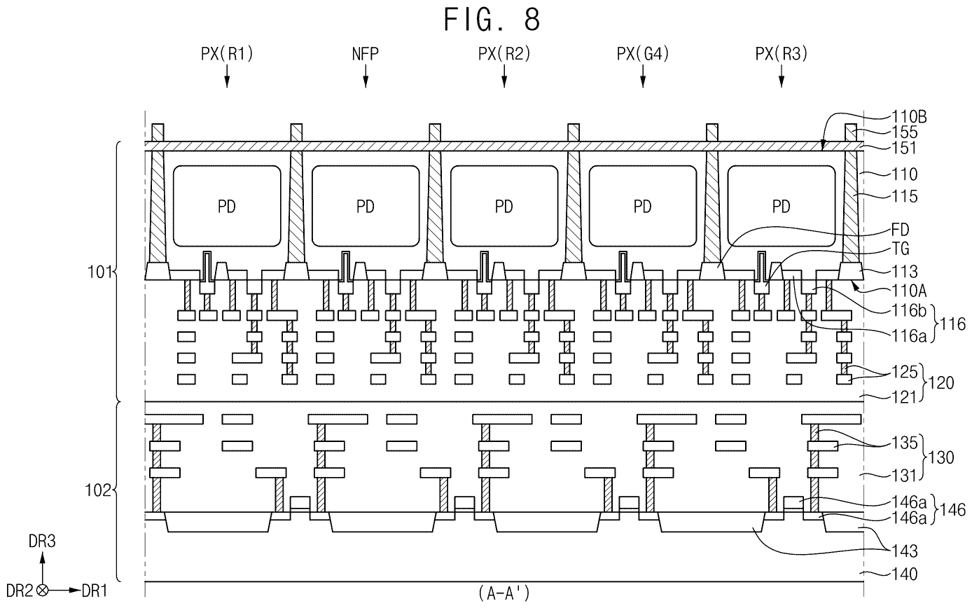

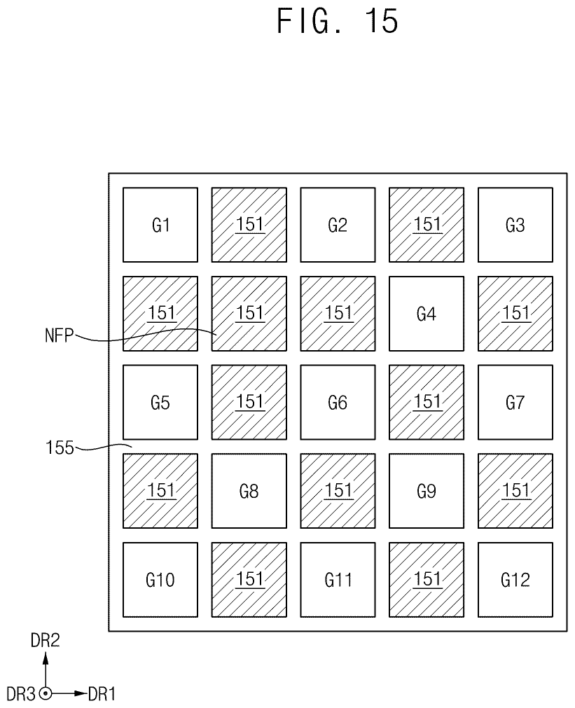

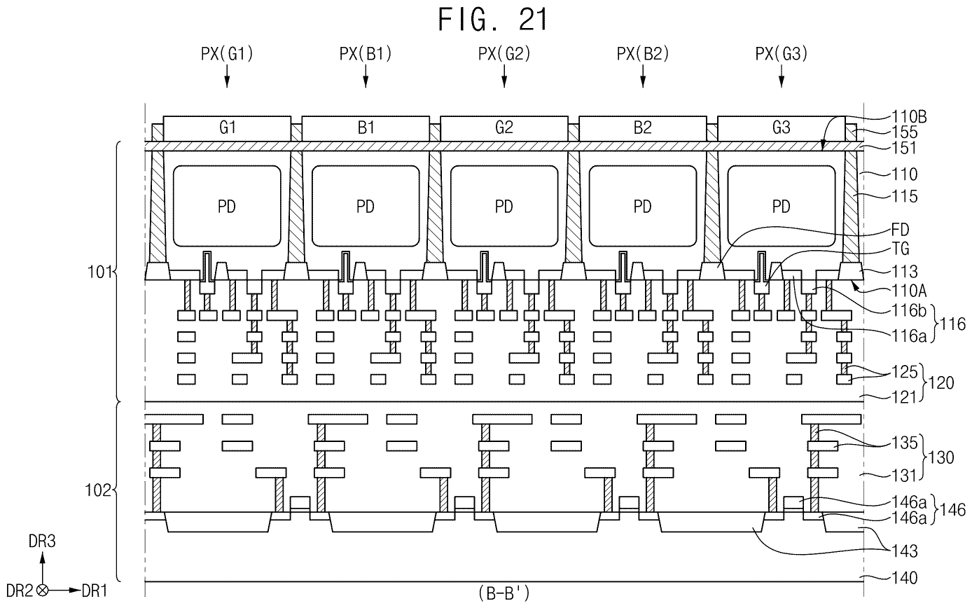

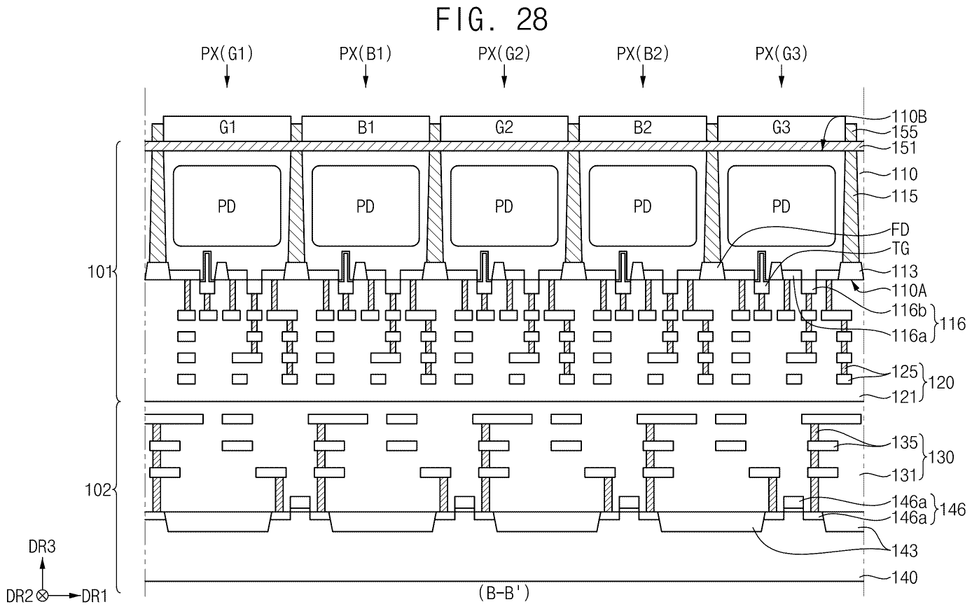

FIGS. 8 to 32 are diagrams for describing a method of manufacturing an image sensor and a thickness measurement according to example embodiments.

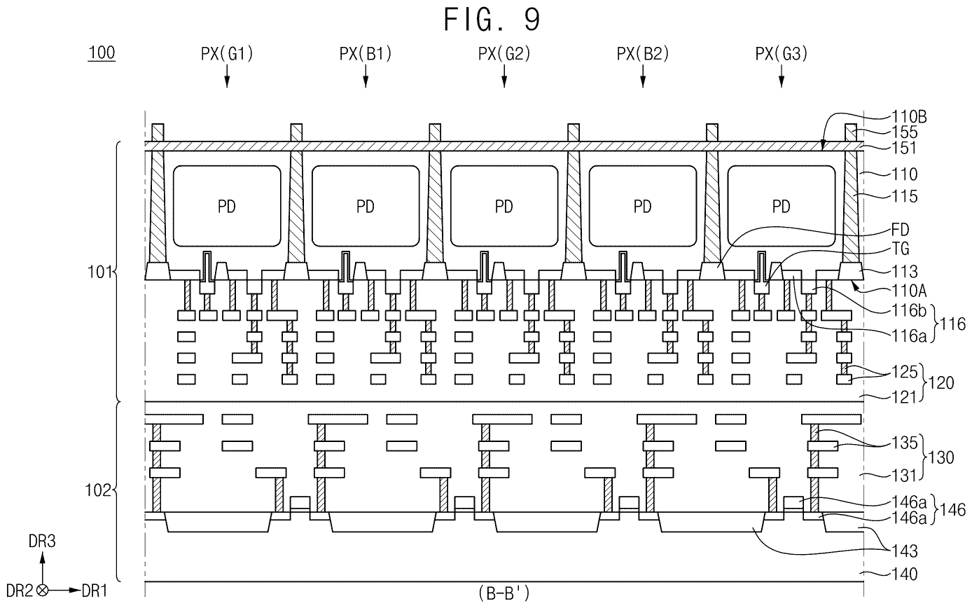

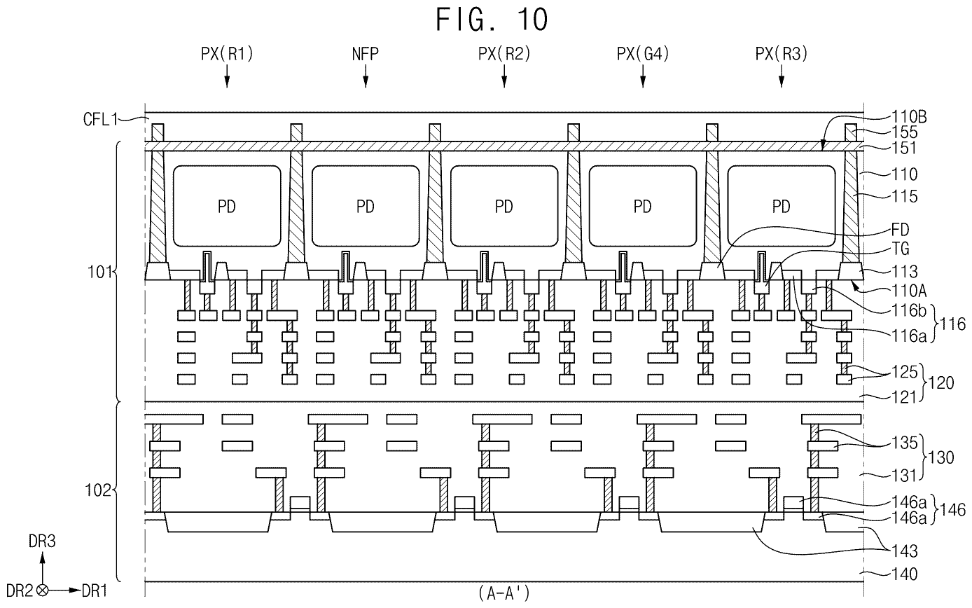

The manufacturing method of FIGS. 8 to 32 may be understood as a method for manufacturing the image sensor 100 illustrated in FIGS. 1 to 3, and the description overlapping with FIGS. 1 to 3 may be omitted. FIGS. 8, 10, 13, 17, 20, 24, 27, and 31 are vertical cross-sectional views taken along line A-A′ of FIG. 1, and FIGS. 9, 11, 14, 18, 21, 25, 28, and 32 are vertical cross-sectional views taken along line B-B′ of FIG. 1, A case in which green filters, blue filters, and red filters are sequentially formed will be described as an example, but the order in which color filters are formed for each color may be varied.

First, referring to FIGS. 8 and 9, after bonding a first wafer for a first semiconductor chip 101 and a second wafer for a second semiconductor chip 102, an insulating film 151 and a light-shielding pattern 155 are formed on a second surface 110B of a first semiconductor substrate 110. This process may be implemented as a wafer-level process. In example embodiments, the first and second semiconductor substrates 110 and 140 may be understood as wafers. The first semiconductor substrate 110 is doped with impurities of a first conductivity type, and impurities of a second conductivity type may be injected into the first semiconductor substrate 110 to form photoelectric conversion elements PD. A device isolation portion 113 may be formed on a first surface 110A of the first semiconductor substrate 110, and a device isolation pattern 115 may be formed in the device isolation portion 113 at a predetermined depth to define pixel regions PX. For example, the device isolation pattern 115 may include polysilicon. A floating diffusion region FD, a transfer gate TG, and various transistors may be formed on the first surface 110B of the first semiconductor substrate 110. A first wiring structure 120 may be formed on the first surface 110B of the first semiconductor substrate 110, thereby manufacturing the first wafer for the first semiconductor chip 101. The manufactured first wafer may be bonded on a second wafer for a second semiconductor chip 102 of a logic circuit. A light-shielding pattern 155 may be disposed on an insulating film 151 to define pixel regions PX. The light-shielding pattern 155 may define spaces for arranging color filters. For example, the light-shielding pattern 155 may include a metal such as tungsten.

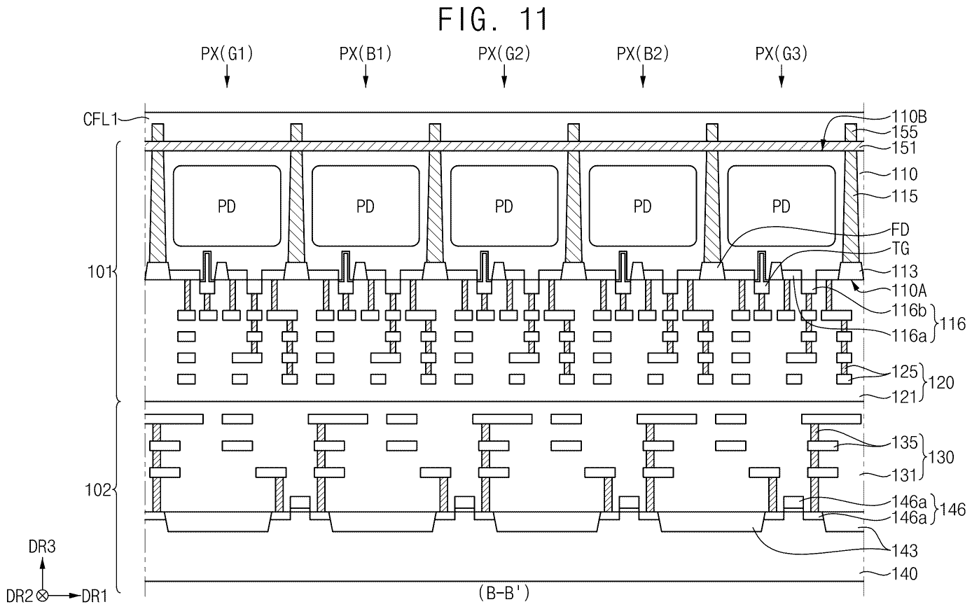

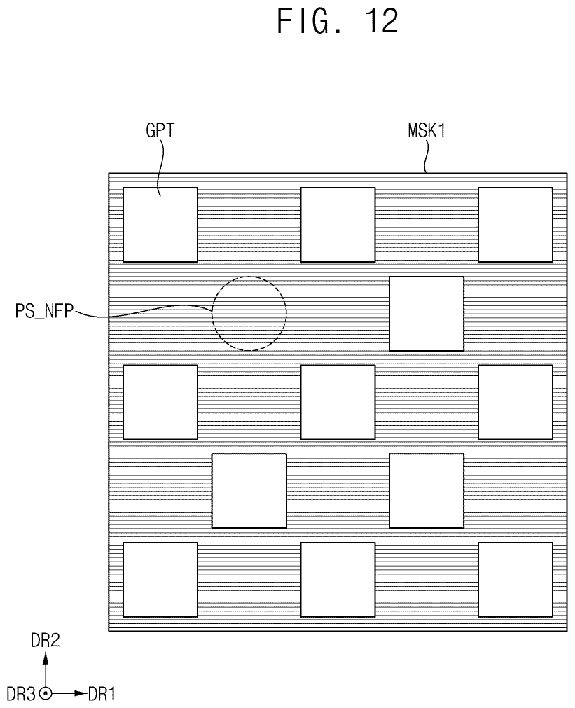

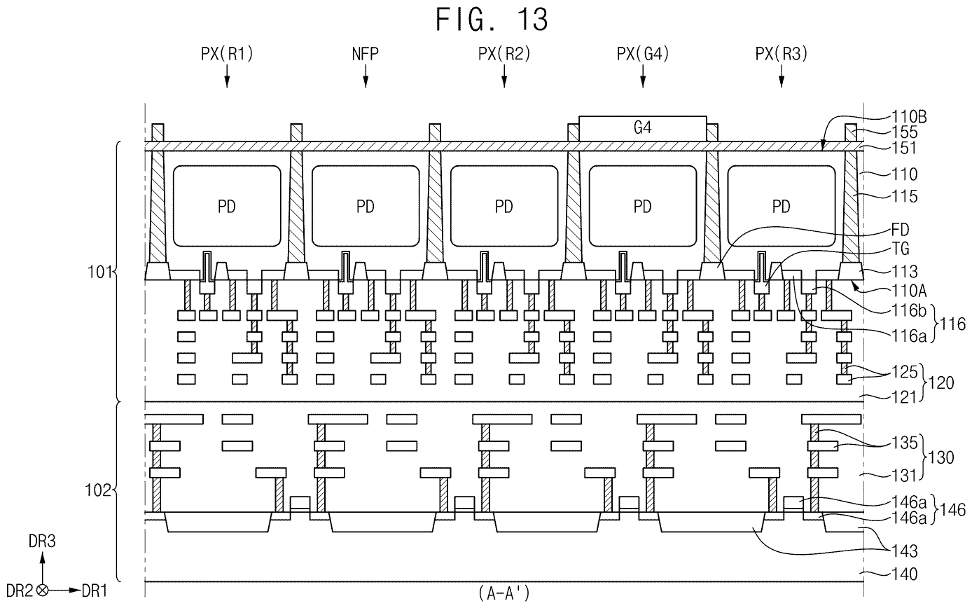

Next, referring to FIGS. 10 and 11, a first color filter layer CFL1 may be formed on the insulating film 151 to fill the spaces defined by the light-shielding pattern 155. The first color filter layer CFL1 may be formed by a coating process, such as spin coating, to fill the spaces between the light-shielding patterns 155. In example embodiments, the first color filter layer CFL1 may include a filter material that transmits green light as a material for green filters. For example, such a filter material may be a photosensitive resin layer containing a dye or pigment having a color filter function. Next, the first color filter layer CFL1 may be patterned. The patterning process of the first color filter layer CFL1 may be performed by exposure and development, and may utilize the first mask MSK1 illustrated in FIG. 12.

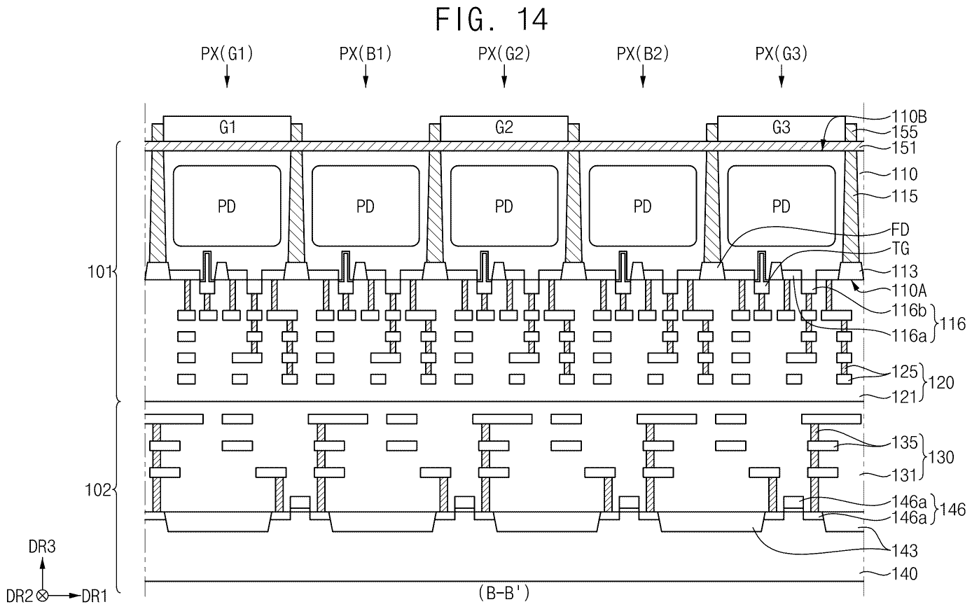

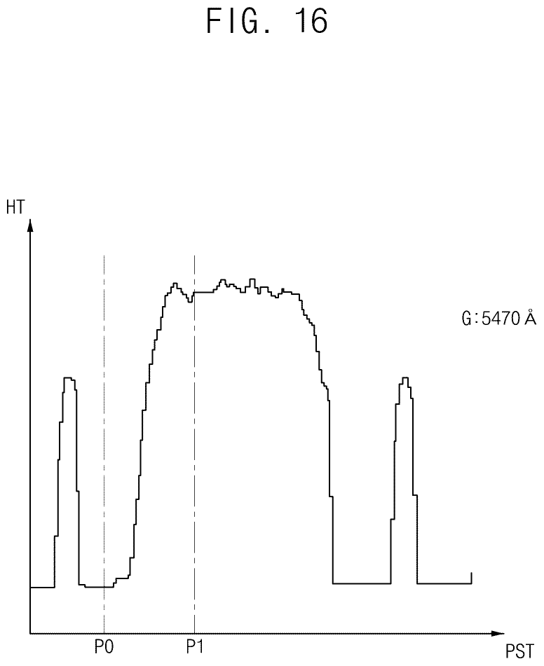

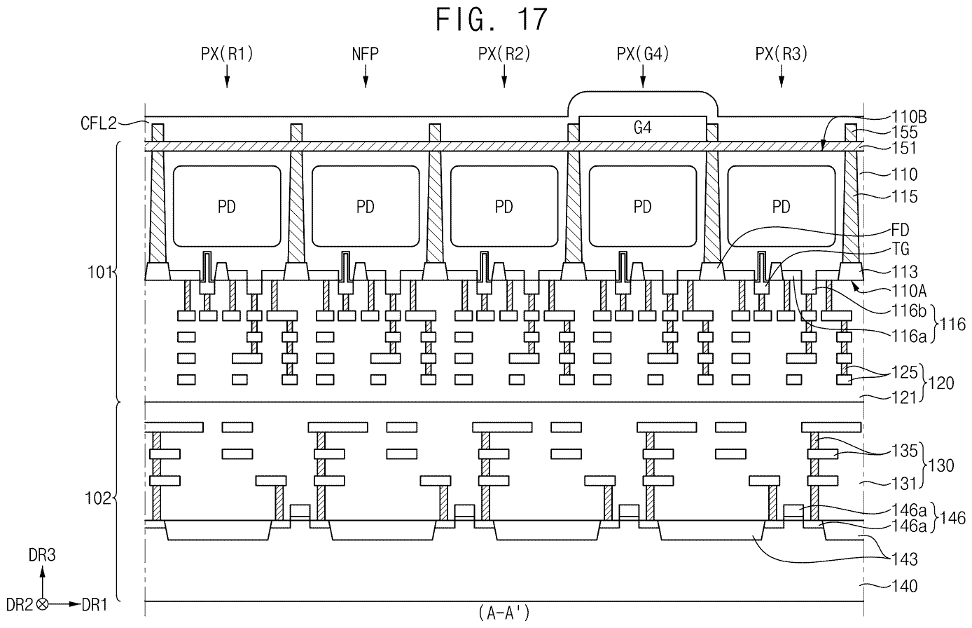

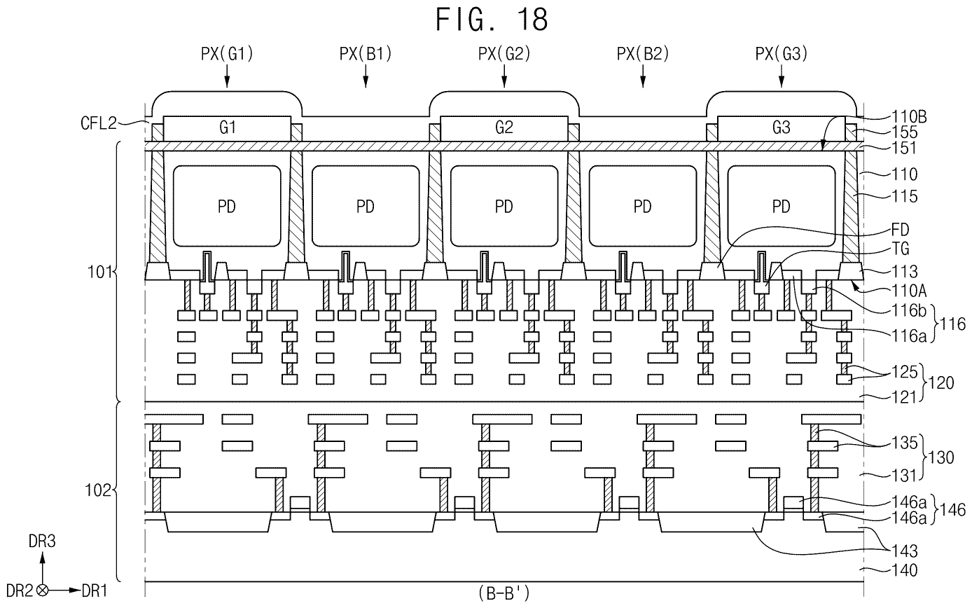

Referring to FIG. 12, the first mask MSK1 may include a plurality of first patterns GPT. The first patterns GPT may all be formed in the same shape. As illustrated in FIG. 12, the first pattern GPT may be omitted at a position PS_NFP corresponding to a non-filter pixel NFP. Through the patterning process using the first mask MSK1, the formation of a color filter corresponding to the non-filter pixel NFP may be prevented. In this way, by patterning the first color filter layer CFL1 using the first mask MSK1 including the plurality of first patterns such that a color filter corresponding to at least one non-filter pixel NFP among the plurality of pixels included in the image sensor is not disposed, a plurality of first color filters corresponding to the plurality of first patterns GPT may be formed. In example embodiments, the plurality of first color filters may correspond to green filters G1 to G12 disposed in spaces between the light-shielding patterns 155 corresponding to green pixels PX(G1) to PX(G12), as illustrated in FIGS. 13 to 15. After forming a plurality of first color filters (for example, green filters G1 to G12 of FIG. 16) and before forming the second color filter layer CFL2 of FIGS. 17 and 18, the thickness of the plurality of first color filters G1 to G12 may be measured.

In example embodiments, the thickness measurement may be performed by an Atomic Force Microscopy (AFM) method, and an example of the measurement result is illustrated in FIG. 16. In FIG. 16, the horizontal axis represents the position PST of the AFM probe, and the vertical axis represents the measured height HT. PO represents the exposed position of the insulating film 151 on which the color filter is not yet formed, and P1 represents the position of the formed green filter G. For example, the measured thickness of the green filter G may be about 5470 A°.

Next, referring to FIGS. 17 and 18, a second color filter layer CFL2 may be formed on the insulating film 151 and the plurality of first color filters (e.g., green filters G1 to G12) such that the spaces defined by the light-shielding pattern 155 are filled. The second color filter layer CFL2 may be formed by a coating process such as spin coating, similar to the first color filter layer CFL1. In example embodiments, the second color filter layer CFL2 may include a filter material that transmits blue light as a material for forming blue filters. For example, such a filter material may be a photosensitive resin layer having a dye or pigment having a color filter function.

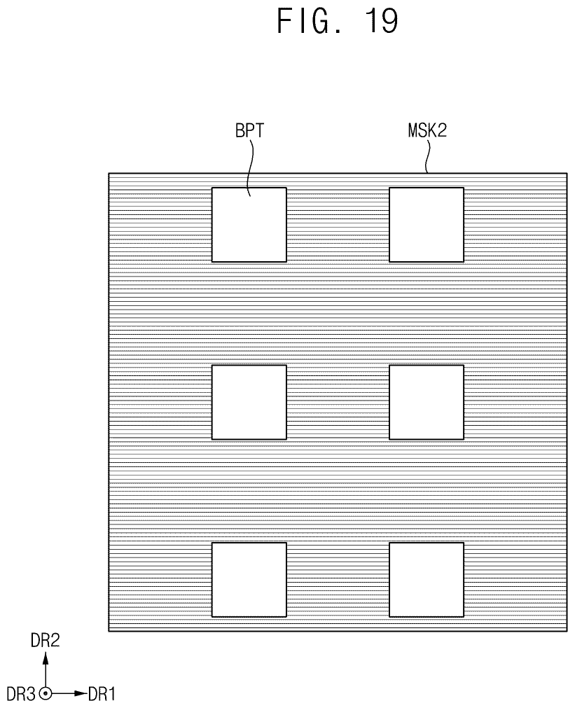

Subsequently, the second color filter layer CFL2 may be patterned. The patterning process of the second color filter layer CFL2 may be performed by exposure and development, and may use the second mask MSK2 as illustrated in FIG. 19.

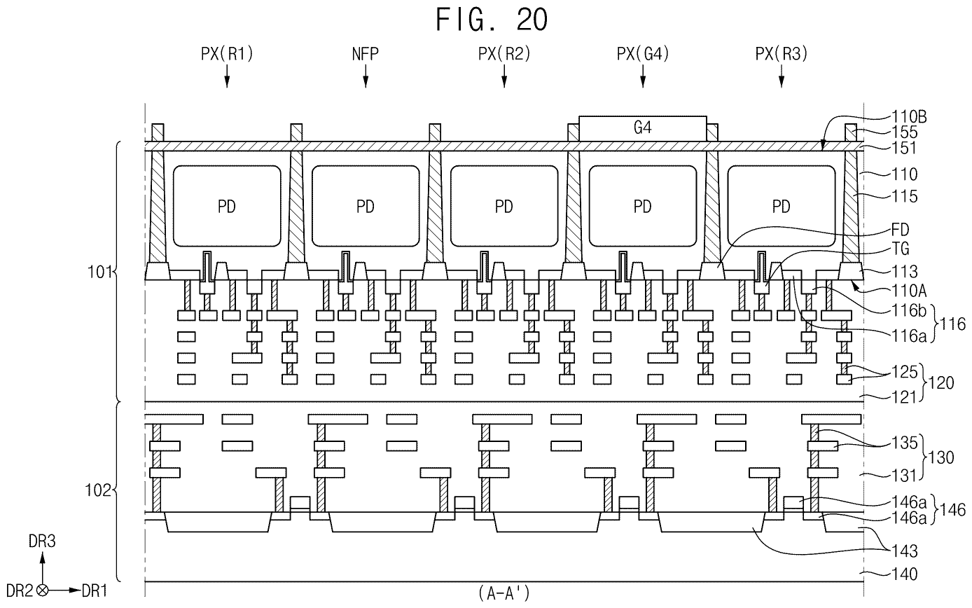

Referring to FIG. 19, the second mask MSK2 may include a plurality of second patterns BPT, and the second patterns BPT may all be formed in the same shape. In this way, the second mask MSK2 including the plurality of second patterns BPT may be used to pattern the second color filter layer CFL2 to form a plurality of second color filters corresponding to the plurality of second patterns BPT. In example embodiments, the plurality of second color filters may correspond to blue filters B1 to B6 arranged in spaces between the light-shielding patterns 155 corresponding to the blue pixels PX(B1) to PX(B6), as illustrated in FIGS. 20 to 22.

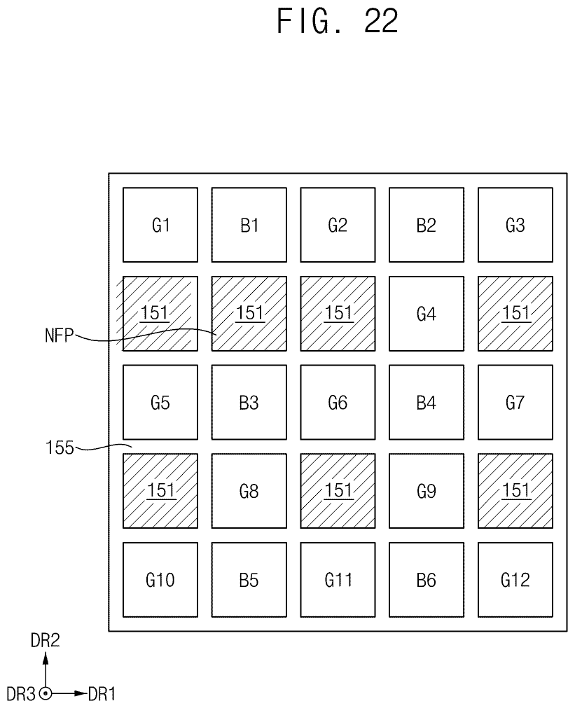

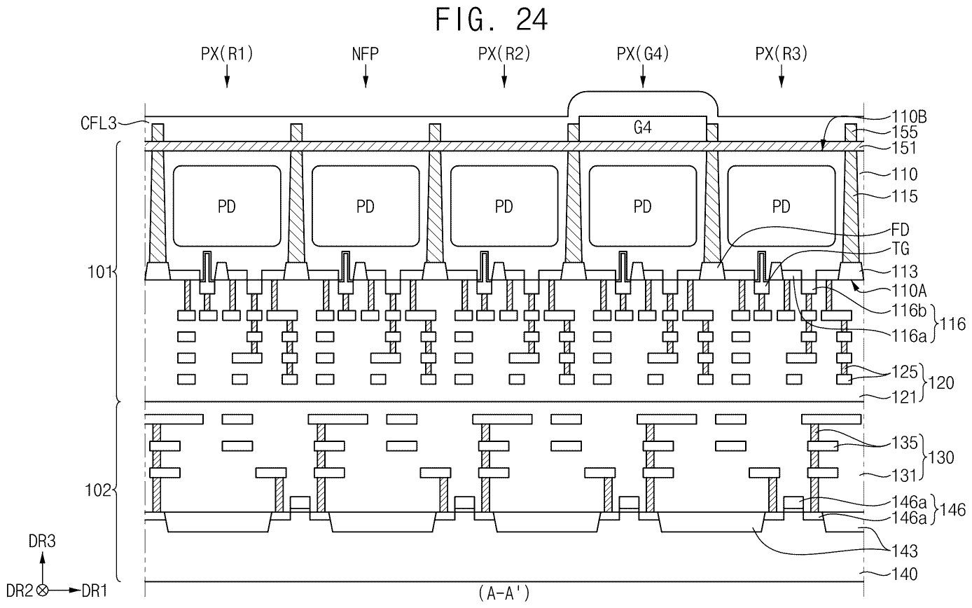

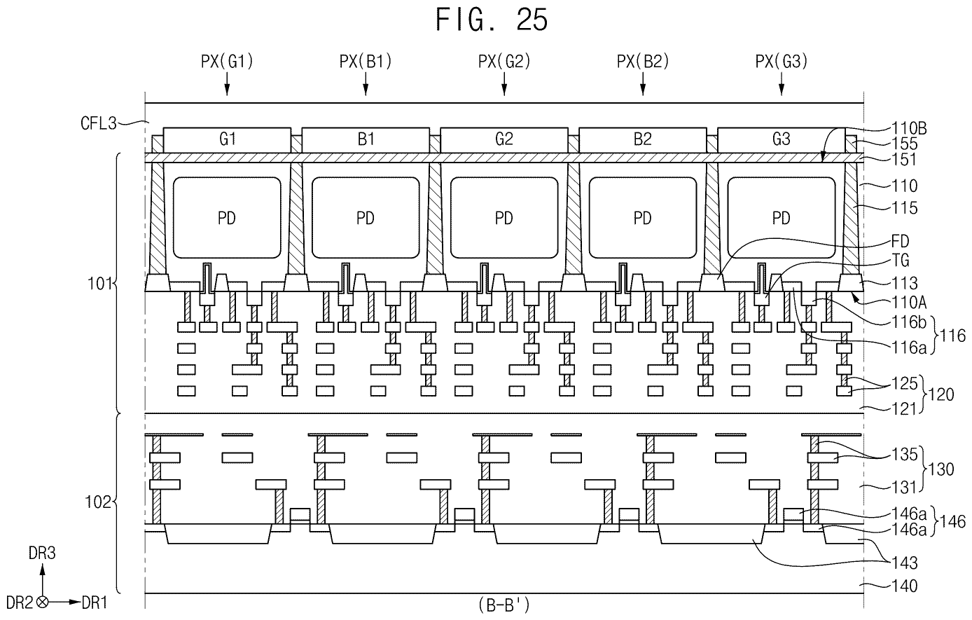

After forming the plurality of second color filters (for example, the blue filters B1 to B6 of FIG. 22) and before forming a third color filter layer CFL3 of FIGS. 24 and 25, the thicknesses of the plurality of first color filters G1 to G12 and the second color filters B1 to B6 may be measured.

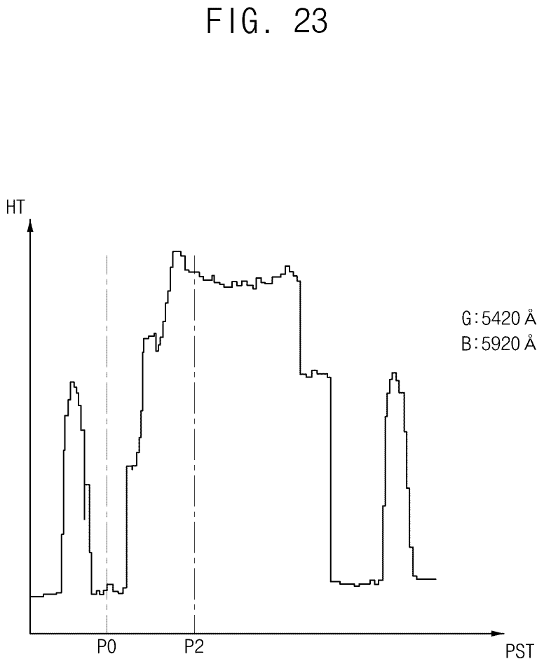

In example embodiments, the thickness may be measured by the AFM (Atomic Force Microscopy) method, and an example of the measurement result is shown in FIG. 23. In FIG. 23, the horizontal axis represents the position PST of the AFM probe, and the vertical axis represents the measured height HT. PO represents the exposure position of the insulating film 151 on which the color filter is not yet formed, and P2 represents the position of the formed blue filter B. The thickness of the green filter G may also be measured in a similar manner. For example, the measured thickness of the green filter G may be 5420 A°, and the measured thickness of the blue filter B may be 5920 A°.

Next, referring to FIGS. 24 and 25, a third color filter layer CFL3 may be formed on the insulating film 151, the plurality of first color filters (e.g., green filters G1 to G12), and the plurality of second color filters (e.g., blue filters B1 to B2) such that spaces defined by the light-shielding pattern 155 are filled. The third color filter layer CFL2 may be formed by a coating process such as spin coating, similar to the first color filter layer CFL1 and the second color filter layer CFL2. In example embodiments, the third color filter layer CFL3 may include a filter material that transmits red light as a material for forming red filters. For example, such a filter material may be a photosensitive resin layer having a dye or pigment having a color filter function.

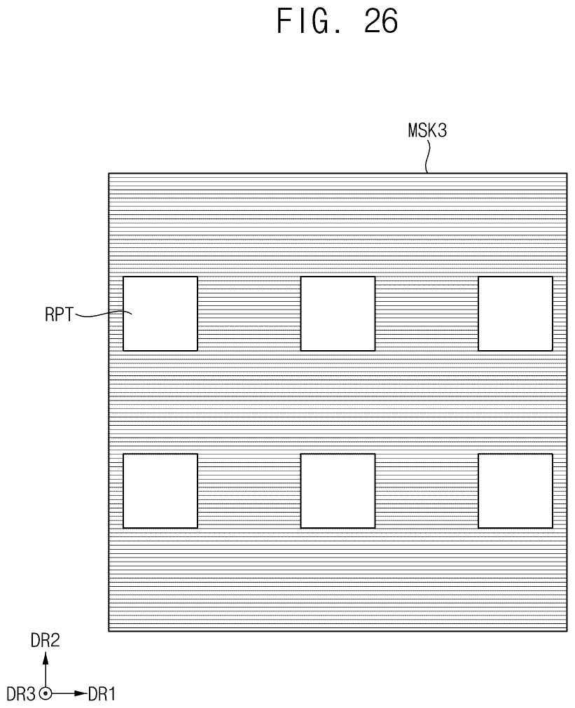

Next, the third color filter layer CFL3 may be patterned. The patterning process of the third color filter layer CFL3 may be performed by exposure and development, and may utilize a third mask MSK3 as illustrated in FIG. 26.

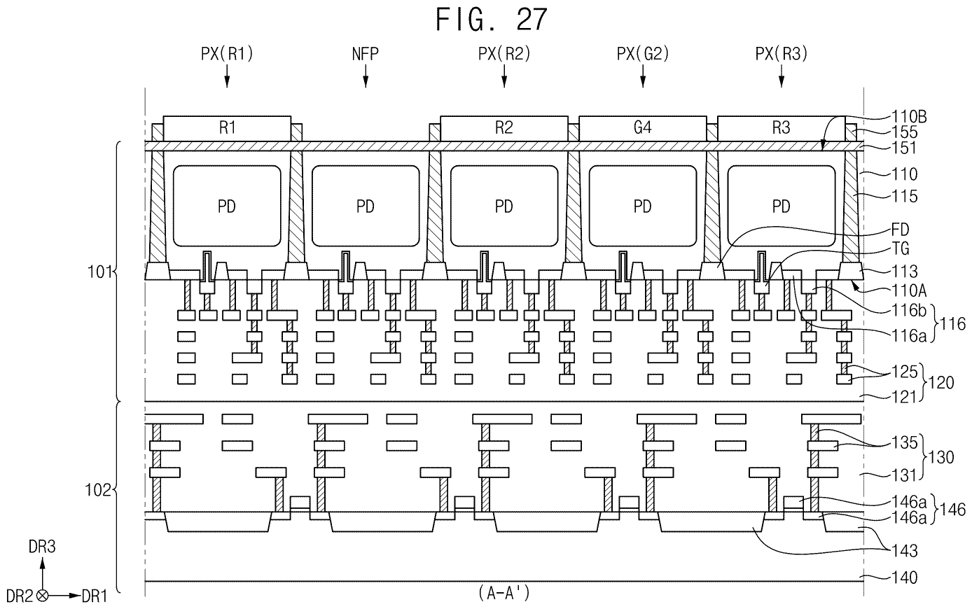

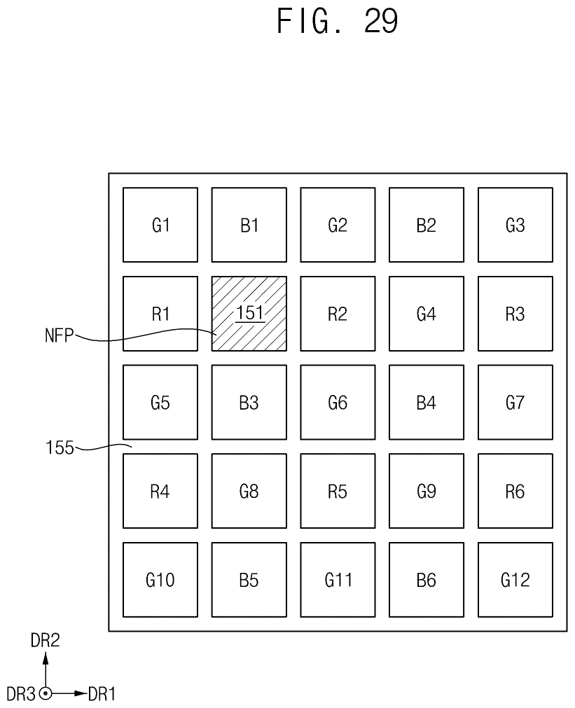

Referring to FIG. 26, the third mask MSK3 may include a plurality of third patterns RPT. The third patterns RPT may all be formed in the same shape. In this manner, the third color filter layer CFL3 may be patterned using the third mask MSK3 including the plurality of third patterns RPT, thereby forming a plurality of third color filters corresponding to the plurality of third patterns RPT. In example embodiments, the plurality of third color filters may correspond to red filters R1 to R6 arranged in spaces between light-shielding patterns 155 corresponding to the red pixels PX(R1) to PX(R6), as illustrated in FIGS. 27 to 29. After forming the plurality of third color filters (for example, the red filters R1 to R6 of FIG. 29), the thicknesses of the plurality of first color filters G1 to G12, the plurality of second color filters B1 to B6, and the plurality of third color filters R1 to R6 may be measured using the non-filter pixel NFP. In example embodiments, the thickness measurement may be performed by an Atomic Force Microscopy (AFM) method, and an example of the measurement result is illustrated in FIG. 30. In FIG. 30, the horizontal axis represents the position PST of the AFM probe, and the vertical axis represents the measured height HT. PO represents the exposure position of the insulating film 151 corresponding to the non-filter pixel NFP, and P3 represents the position of the formed red filter R. In a similar manner, the thickness of the green filter G and the thickness of the blue filter B may also be measured. For example, the measured thickness of the green filter G is 4980 A°, the measured thickness of the blue filter B is 5585 A°, and the measured thickness of the red filter G is 5591 A°.

In this way, after all color filters are formed, the thicknesses of the plurality of color filters, i.e., the thickness of the green filter G, the thickness of the blue filter B, and the thickness of the red filter R, may all be measured using the surface of the insulating film 151 corresponding to the non-filter pixel NFP as a reference surface.

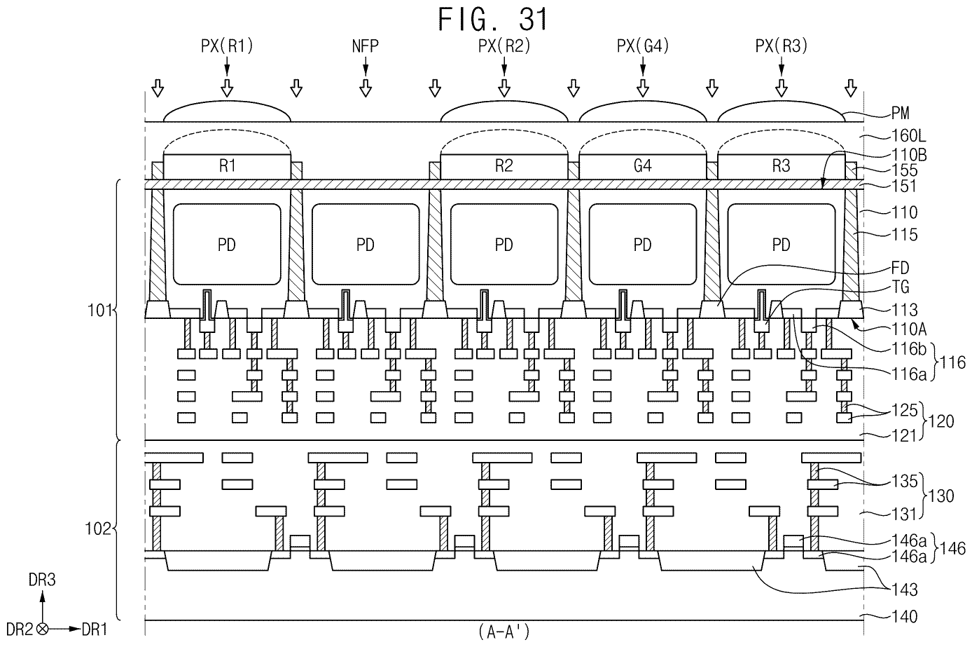

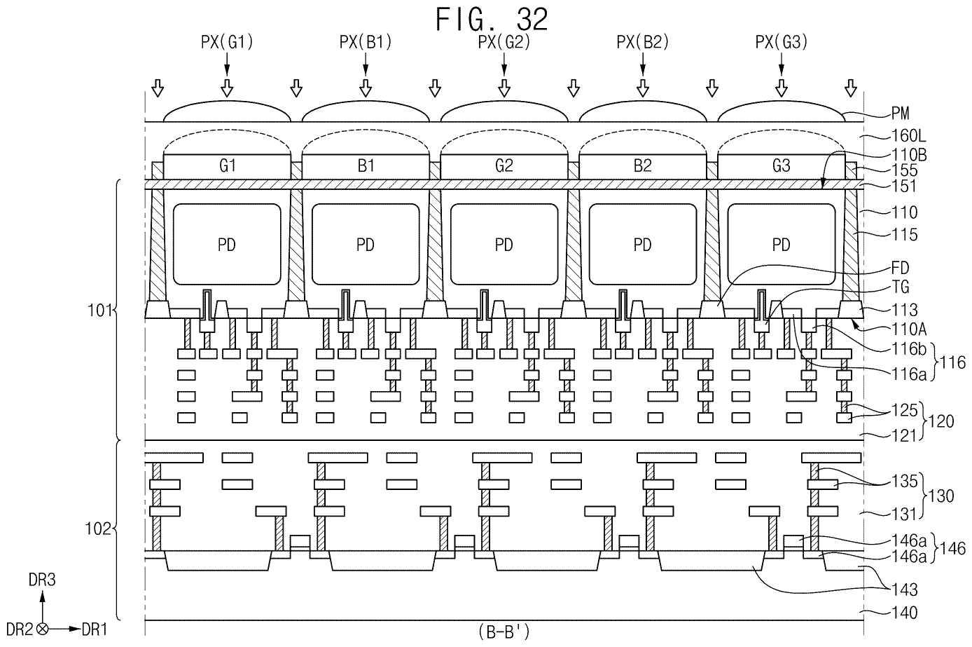

Next, referring to FIGS. 31 and 32, a lens material layer 160L is formed on the plurality of color filters G1 to G12, B1 to B6, and R1 to R6, and then sacrificial patterns PM having a desired lens shape may be formed on the lens material layer 160L. For example, the lens material layer 160L may be a transparent resin with excellent light transmittance. The lens material layer 160) may be formed to have a substantially flat upper surface. The sacrificial patterns (PM) are arranged on the lens material layer 160L and may be processed to have a desired lens shape in each pixel region PX. The sacrificial patterns PM may be formed by forming a sacrificial material layer, then patterning the sacrificial patterns PM, and reflowing the sacrificial patterns PM to have a lens shape. Subsequently, an etching process of the lens material layer 160L together with the sacrificial patterns PM may be performed to transfer the shape of the sacrificial patterns PM to the lens material layer 160L. This etching process may be performed until the sacrificial patterns PM are removed, resulting in the formation of a microlens layer 160 indicated by a dotted line in FIGS. 31 and 32.

As illustrated in FIG. 31, the sacrificial pattern PM may be omitted at a position corresponding to the non-filter pixel NFP, and a microlens may not be arranged on the non-filter pixel NFP.

FIG. 33 is a plan view illustrating an image sensor according to example embodiments.

FIG. 33 illustrates a tetra pattern in which four green filters G are arranged adjacent to one another, four blue filters B are arranged adjacent to one another, and four red filters R are arranged adjacent to one another to form each group, and two groups of green filters G, one group of blue filters B, and one group of red filters R are arranged in a Bayer pattern.

Referring to FIG. 33, at least one non-filter pixel included in the image sensor may include a plurality of non-filter pixels NFP1, NFP2, NFP3, and NFP4, and the plurality of non-filter pixels NFP1, NFP2, NFP3, and NFP4 may be arranged adjacent to one another to form a non-filter pixel group.

In example embodiments, as illustrated in FIG. 33, the plurality of non-filter pixels NFP1, NFP2, The NFP3, and NFP4 may include a first non-filter pixel NFP11, a second non-filter pixel NFP12, a third non-filter pixel NFP21, and a fourth non-filter pixel NFP22. The second non-filter pixel NFP12 may be arranged adjacent to the first non-filter pixel NFP11 in the first horizontal direction DR1. The third non-filter pixel NFP21 may be arranged adjacent to the first non-filter pixel NFP11 in the second horizontal direction DR2. The fourth non-filter pixel NFP22 may be arranged adjacent to the second non-filter pixel NFP12 in the second horizontal direction DR2 and adjacent to the third non-filter pixel NFP21 in a first

horizontal direction DR1. As a result, the first non-filter pixel NFP11, the second The non-filter pixel NFP12, the third non-filter pixel NFP21, and the fourth non-filter pixel NFP22 may be arranged in a matrix form of two rows and two columns.

In example embodiments, as illustrated in FIG. 33, the first non-filter pixel NFP11, the second non-filter pixel NFP12, the third non-filter pixel NFP21, and the fourth non-filter pixel NFP22 may all correspond to pixels from which the green filters G are omitted.

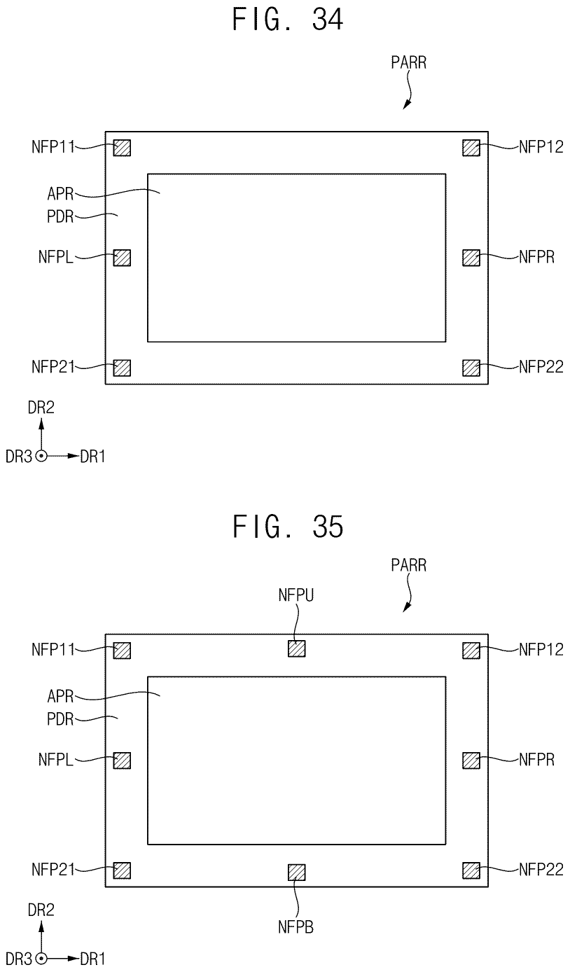

FIGS. 34 to 36 are diagrams illustrating examples of arrangement of non-filter pixels included in an image sensor according to example embodiments.

Referring to FIGS. 34 to 36, a pixel array PARR of an image sensor may include an active pixel region APR corresponding to a central portion of a semiconductor substrate and a dummy pixel region PDR surrounding the active pixel region APR. The active pixel region APR may include active pixels, and the dummy pixel region PDR may include dummy pixels. The dummy pixels have a structure similar to the active pixels, but correspond to pixels that do not perform the sensing operation (i.e., generating a photoelectric signal by receiving light) like active pixels.

The aforementioned non-filter pixel NFP may correspond to a dummy pixel arranged in the dummy pixel region PDR.

In example embodiments, as illustrated in FIG. 34, the perimeter of the dummy pixel region PDR has a rectangular shape, and at least one non-filter pixel NFP may include a plurality of corner non-filter pixels NFP11, NFP12, NFP21, and NFP22 arranged at four corners of the rectangular shape.

In example embodiments, as illustrated in FIG. 35, the aforementioned at least one non-filter pixel NFP may further include a plurality of side non-filter pixels NFPU, NFPR, NFPB, and NFPL arranged at four sides of the rectangular shape.

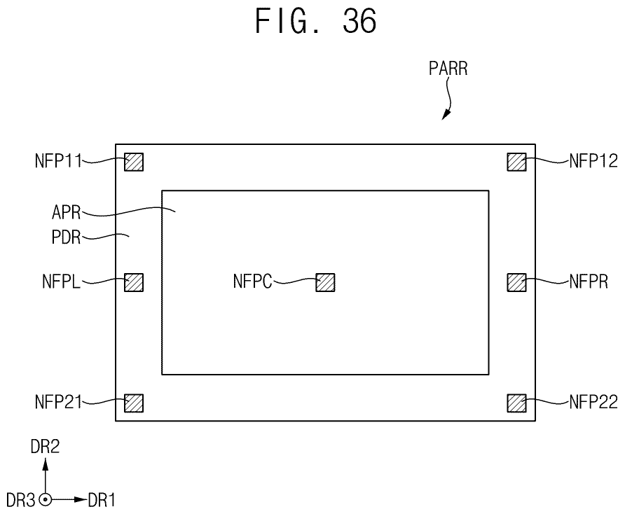

In example embodiments, as illustrated in FIG. 36, the aforementioned at least one non-filter pixel NFP may further include at least one central non-filter pixel NFPC arranged in the active pixel region APR. Since the central non-filter pixel NFPC does not include a color filter, the central non-filter pixel NFPC cannot function as an active pixel. In this case, the pixel signal (Vout in FIGS. 5 to 7) corresponding to the central non-filter pixel NFPC may be provided by interpolating the pixel signals of neighboring pixels adjacent to the central non-filter pixel NFPC. In this way, by optimizing the number and arrangement of non-filter pixels, it is possible to accurately provide deviations according to the thickness and position of color filters within the pixel array. Furthermore, by arranging a plurality of non-filter pixels, the function of the non-filter pixels as a pixel count marker for identifying the positions of a plurality of pixels included in the image sensor may be enhanced.

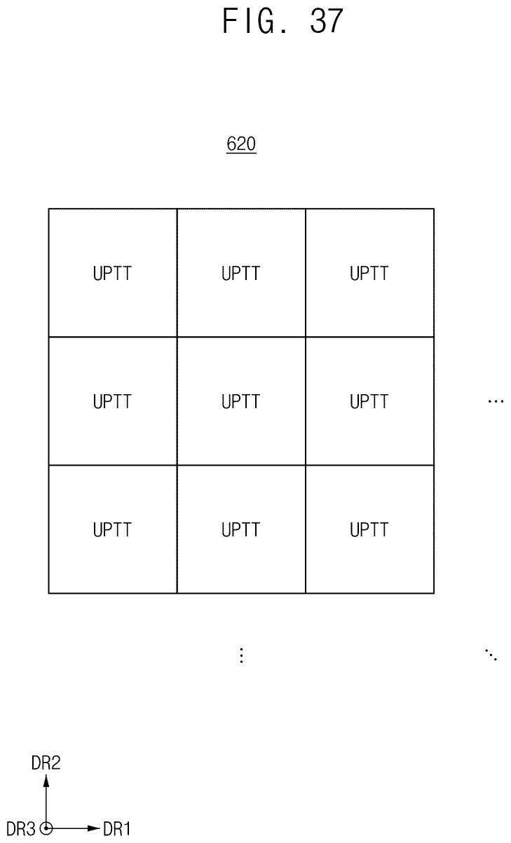

FIG. 37 is a diagram illustrating a layout of a pixel array according to example embodiments, and FIGS. 38 to 47 are plan views illustrating example embodiments of a unit pixel included in the pixel array of FIG. 37.

Referring to FIG. 37, the pixel array 620 in the image sensor 500 of FIG. 4 may be divided into unit patterns UPTT that are arranged repeatedly in the first horizontal direction DR1 and the second horizontal direction DR2. Each unit pattern UPTT may include two or more pixel groups where each pixel group may include a plurality of unit pixels sharing a common microlens CMLS.

In some example embodiments, all of the unit patterns UPTT in the pixel array 620 may be identical, except a case that a non-filter pixel is included in a unit pattern. In this case, the unit pattern UPTT is a minimum pattern that cannot be divided into smaller patterns. In some example embodiments, the unit patterns UPTT in the pixel array 620 may include two or more different patterns such that the different patterns are arranged regularly in the first horizontal direction DR1 and/or the second horizontal direction DR2.

Hereinafter, various color filter array and unit patterns according to example embodiments are described with reference to FIGS. 38 through 47. The unit pattern may be inverted in the first horizontal direction DR1 and/or the second horizontal direction DR2, or the unit pattern may be rotated around the vertical direction by 90 degrees or 180 degrees.

In FIGS. 38 through 47, a unit pixel corresponding to a red filter is referred to as a red pixel R, a unit pixel corresponding to a green filter is referred to as a green pixel G, a unit pixel corresponding to a blue filter is referred to as a blue pixel B, a unit pixel corresponding to a yellow filter is referred to as a yellow pixel Y, and a unit pixel corresponding to a cyan filter is referred to as a cyan pixel C. For a pixel group PXGij, i indicates an index of a corresponding group row, and j indicates an index of a corresponding group column. When the unit pixels in each pixel group correspond to the same color, the unit pixels in each pixel group may share a single color filter CF.

FIGS. 38 through 44 are plan views illustrating example embodiments of a unit pattern of a 4*4 size included in a pixel array according to example embodiments.

Referring to FIGS. 38 through 44, each of unit patterns UPTT1~UPTT7 having a 4*4 size may include first through fourth pixel groups PXG11~PXG22 arranged in a matrix form of two group rows GR1 and GR2 and two group columns GC1 and GC2. Each of the first through fourth pixel groups PXG11~PXG22 may include four unit pixels arranged in a matrix form of two pixel rows and two pixel columns.

In some example embodiments, as the unit pattern UPTT1 illustrated in FIG. 38, the first pixel group PXG11 may include four red pixels R, each of the second and third pixel groups PXG12 and PXG21 may include four green pixels G, and the fourth pixel group PXG22 may include four blue pixels B.

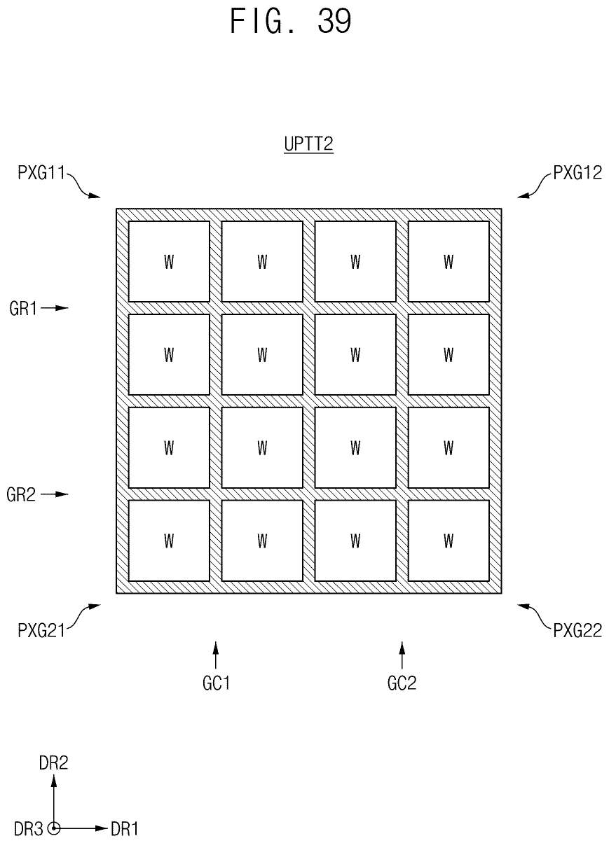

In some example embodiments, as the unit pattern UPTT2 illustrated in FIG. 39, each of the first through fourth pixel groups PXG11~PXG22 may include four white pixels W.

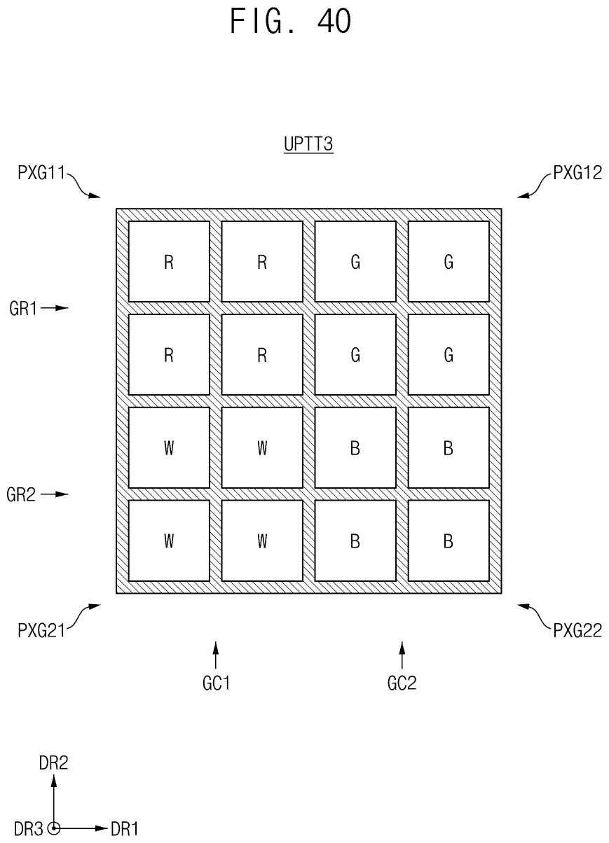

In some example embodiments, as the unit pattern UPTT3 illustrated in FIG. 40, the first pixel group PXG11 may include four red pixels R, the second pixel group PXG12 may include four green pixels G, the third pixel group PXG21 may include four white pixels W, and the fourth pixel group PXG22 may include four blue pixels B.

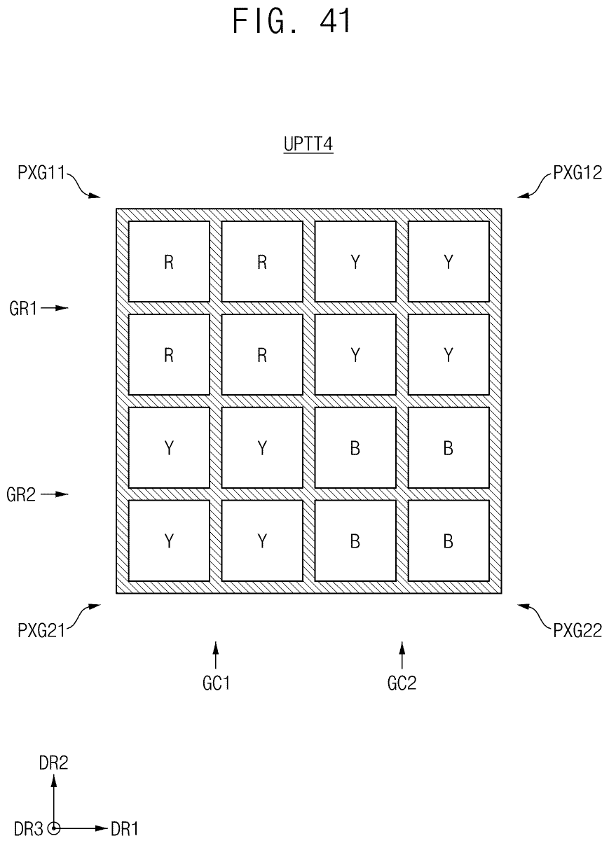

In some example embodiments, as the unit pattern UPTT4 illustrated in FIG. 41, the first pixel group PXG11 may include four red pixels R, each of the second and third pixel groups PXG12 and PXG21 may include four yellow pixels Y, and the fourth pixel group PXG22 may include four blue pixels B.

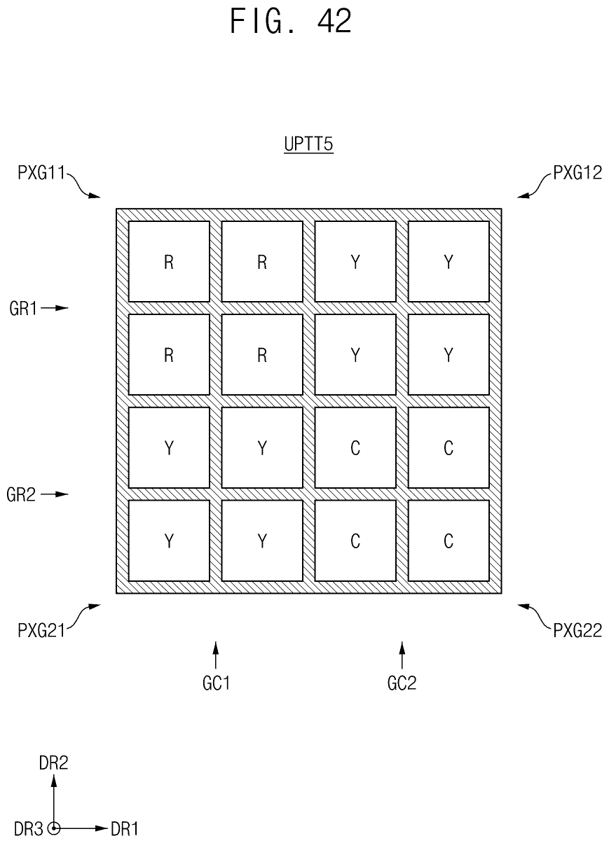

In some example embodiments, as the unit pattern UPTT5 illustrated in FIG. 42, the first pixel group PXG11 may include four red pixels R, each of the second and third pixel groups PXG12 and PXG21 may include four yellow pixels Y, and the fourth pixel group PXG22 may include four cyan pixels C.

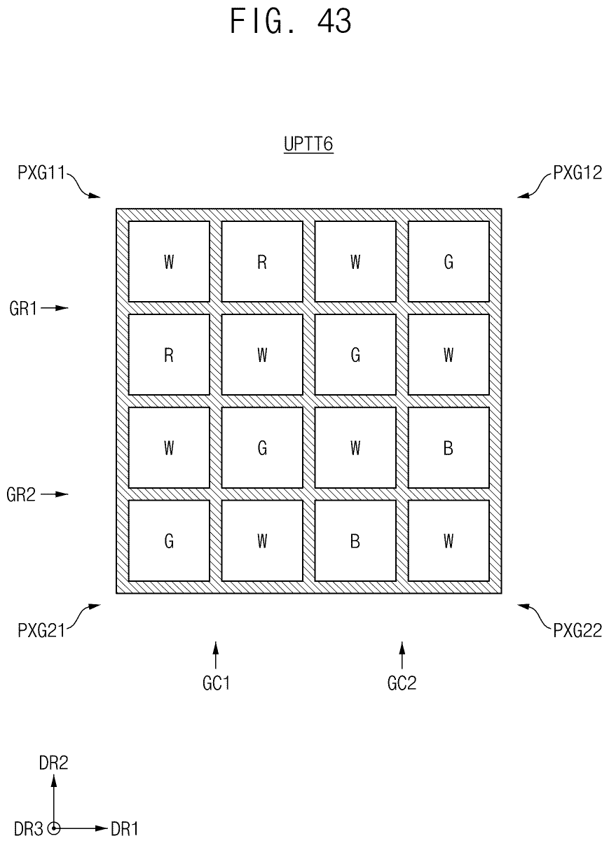

In some example embodiments, as the unit pattern UPTT6 illustrated in FIG. 43, the first pixel group PXG11 may include two red pixels R and two white pixels W, each of the second and third pixel groups PXG12 and PXG21 may include two green pixels G and two white pixels W, and the fourth pixel group PXG22 may include two blue pixels B and two white pixels W.

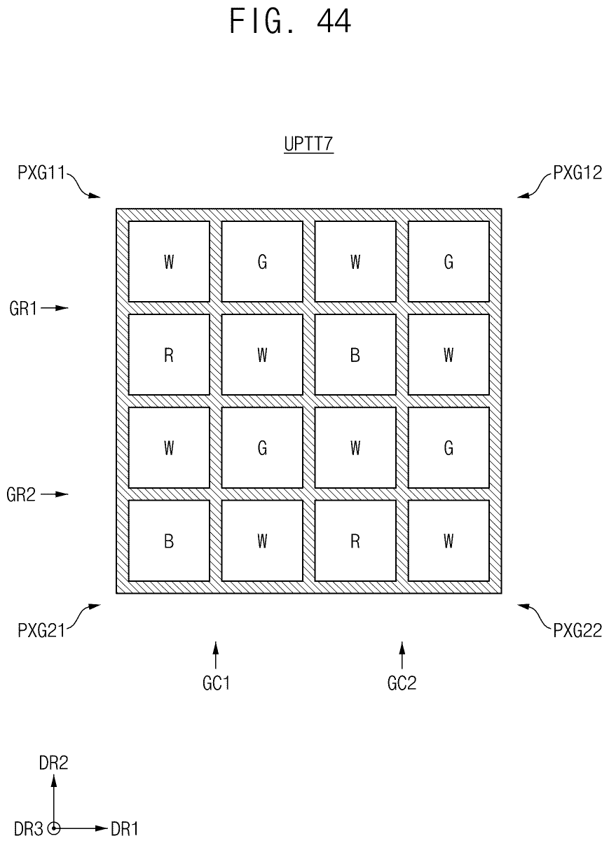

In some example embodiments, as the unit pattern UPTT7 illustrated in FIG. 44, each of the first and fourth pixel groups PXG11 and PXG22 may include two white pixels W, one green pixel G and one red pixel R, each of the second and third pixel groups PXG12 and PXG21 may include two white pixels W, one green pixel G and one blue pixel B.

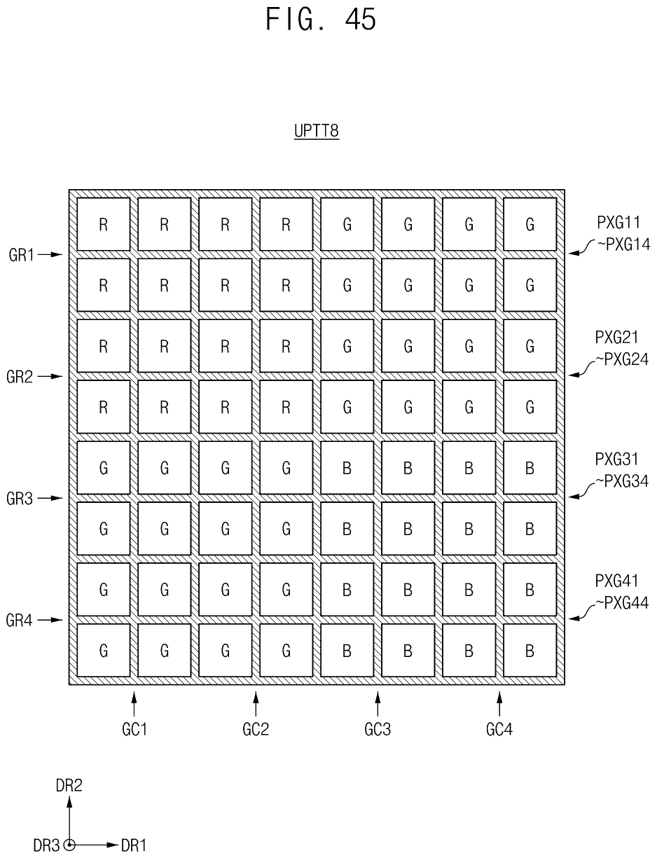

FIGS. 45 through 47 are plan views illustrating example embodiments of a unit pattern of a 8*8 size included in a pixel array according to example embodiments.

Referring to FIGS. 44 through 47, each of unit patterns UPTT8~UPTT10 having a 8*8 size may include first through sixteenth pixel groups PXG 11~PXG44 arranged in a matrix form of first through fourth group rows GR1~GR4 and first through fourth group columns GC1~GC4. The first through fourth pixel groups PXG11, PXG12, PXG21 and PXG22 may be arranged in a matrix form of the first and second group rows GR1 and GR2 and the first and second group columns GC1 and GC2. The fifth through eighth pixel groups PXG13, PXG14, PXG23 and PXG24 may be arranged in a matrix form of the first and second group rows GR1 and GR2 and the third and fourth group columns GC3 and GC4. The ninth through twelfth pixel groups PXG31, PXG32, PXG41 and PXG42 may be arranged in a matrix form of the third and fourth group rows GR3 and GR4 and the first and second group columns GC1 and GC2. The thirteenth through sixteenth pixel groups PXG33, PXG34, PXG43 and PXG44 may be arranged in a matrix form of the third and fourth group rows GR3 and GR4 and the third and fourth group columns GC3 and GC4. Each of the first through sixteenth pixel groups PGX11~PGX44 may include four unit pixels arranged in a matrix form of two pixel rows and two pixel columns.

In some example embodiments, as the unit pattern UPTT8 illustrated in FIG. 45, each of the first through fourth pixel groups PXG11, PXG12, PXG21 and PXG22 may include four red pixels R, each of the fifth through twelfth pixel groups PXG13, PXG14, PXG23, PXG24, PXG31, PXG32, PXG41 and PXG42 may include four green pixels G, and each of the thirteenth through sixteenth pixel groups PXG33, PXG34, PXG43 and PXG44 may include four red pixels R.

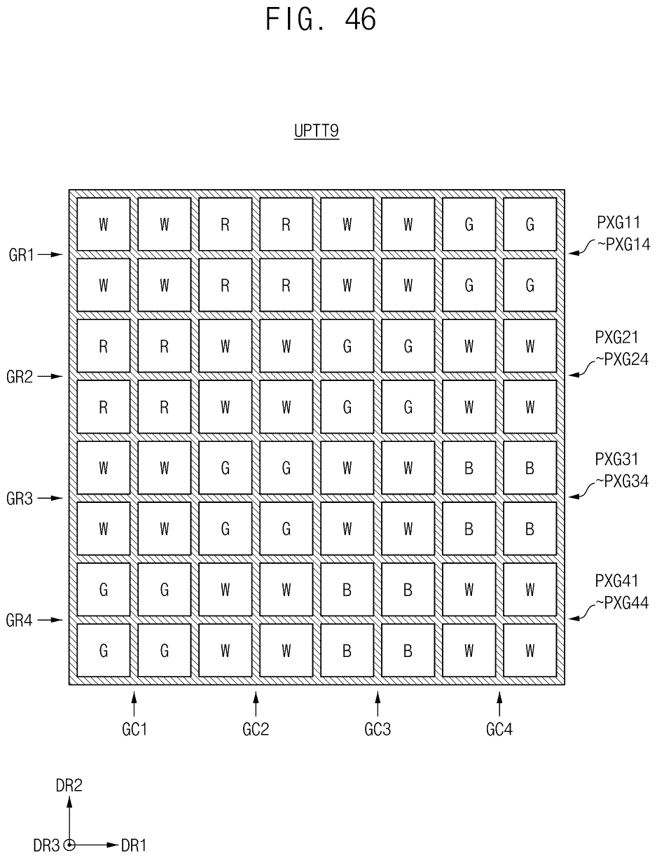

In some example embodiments, as the unit pattern UPTT9 illustrated in FIG. 46, each of the first, fourth, fifth, eighth, ninth, twelfth, thirteenth and sixteenth pixel groups PXG11, PXG22, PXG13, PXG24, PXG31, PXG42, PXG33 and PXG44 may include four white pixels W, each of the second and third pixel groups PXG12 and PXG21 may include four red pixels R, each of the sixth, seventh, tenth and eleventh pixel groups PXG14, PXG23, PXG32 and PXG41 may include four green pixels G, and each of the thirteenth and fifteenth pixel groups PXG34 and PXG43 may include four blue pixels B.

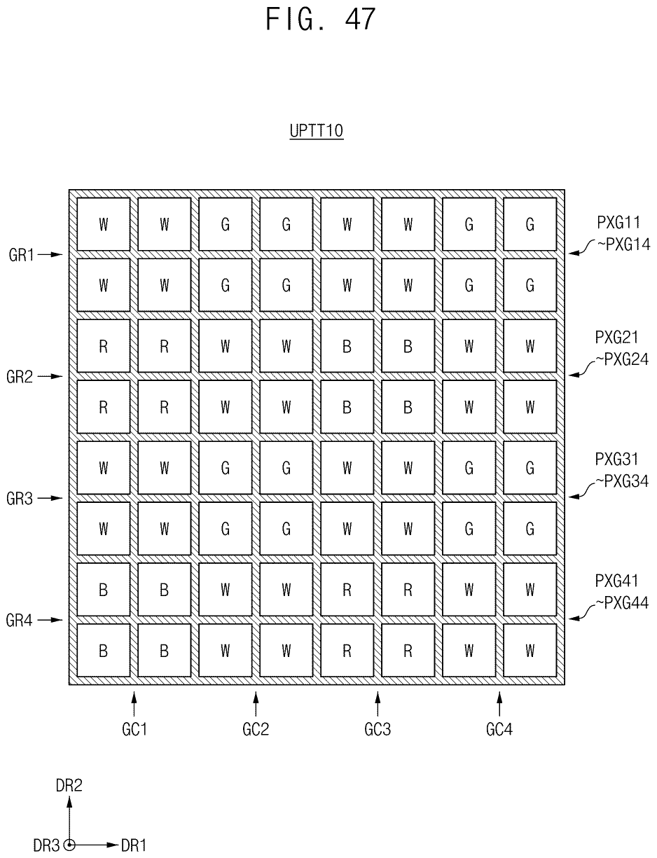

In some example embodiments, as the unit pattern UPTT10 illustrated in FIG. 47, each of the first, fourth, fifth, eighth, ninth, twelfth, thirteenth and sixteenth pixel groups PXG11, PXG22, PXG13, PXG24, PXG31, PXG42, PXG33 and PXG44 may include four white pixels W, each of the third and fifteenth pixel groups PXG21 and PXG43 may include four red pixels R, each of the second, sixth, tenth and fourteenth pixel groups PXG12, PXG14, PXG32 and PXG34 may include four green pixels G, and each of the seventh and eleventh pixel groups PXG23 and PXG41 may include four blue pixels B.

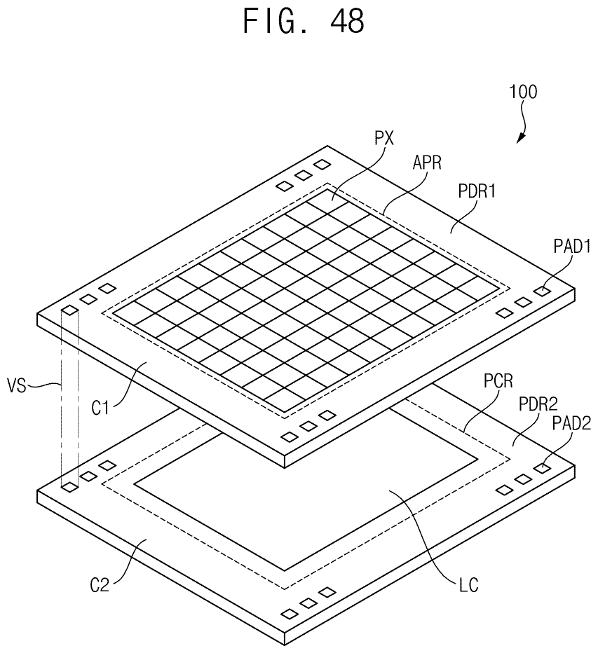

FIG. 48 is a diagram illustrating a perspective view illustrating an image sensor according to example embodiments.

Referring to FIG. 48, an image sensor 100 may be a stacked image sensor including a first chip C1 and a second chip C2 stacked in a vertical direction. The first chip C1 may include an active pixel region APR and a first pad region PDR1, and the second chip C2 may include a peripheral circuit region PCR and a second pad region PDR2.

A plurality of first pads PAD1 of the first pad region PDR1 may be configured to transmit and receive electrical signals to and from an external device or the like. The peripheral circuit region PCR may include a logic circuit block LC, which may include a plurality of CMOS transistors. The peripheral circuitry region PCR may provide a signal to each active pixel PX of the active pixel region APR or may control an output signal from each active pixel PX. The first pad PAD1 in the first pad region PDR1 may be electrically connected, through a via structure VS, to the second pad PAD2 in the second pad region PDR2.

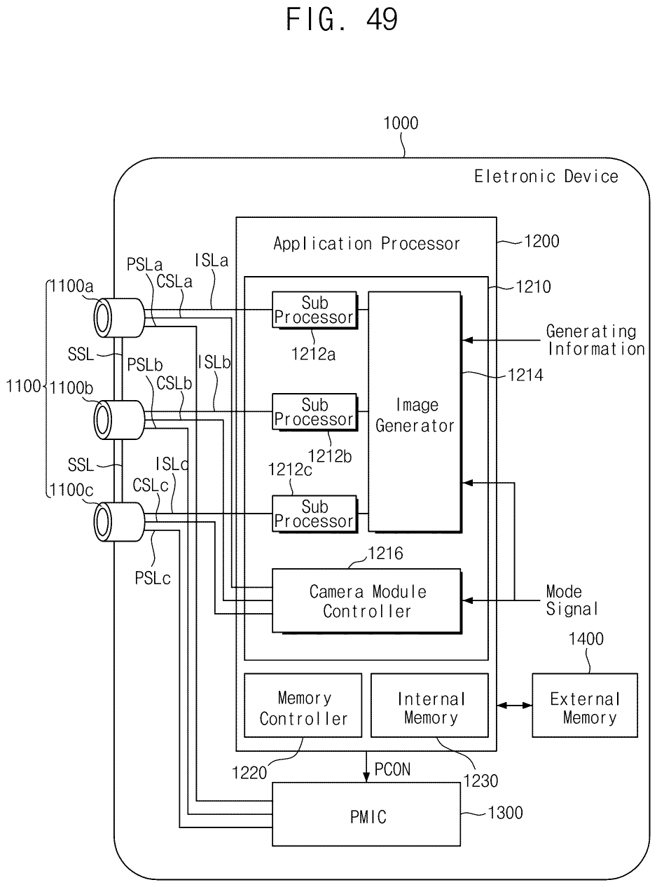

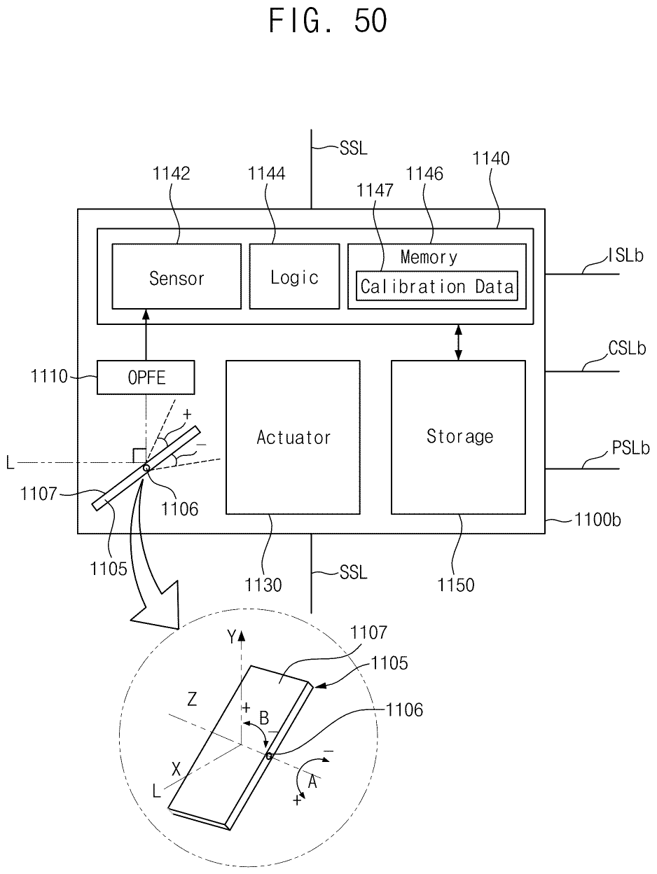

FIG. 49 is a block diagram illustrating an electronic device according to example embodiments, and FIG. 50 is a block diagram illustrating a camera module included in the electronic device of FIG. 49.

Referring to FIG. 49, an electronic device 1000 may include a camera module group 1100, application processor 1200, a power management integrated circuit (PMIC) 1300 and/or an external memory 1400.

The camera module group 1100 may include a plurality of camera modules 1100a, 1100b, and 1100c. FIG. 49 illustrates the three camera modules 1100a, 1100b, and 1100c as an example, but example embodiments are not limited to a particular number of camera modules. According to example embodiments, the camera module group 1100 may include two camera modules, and four or more camera modules.

Hereinafter, an example configuration of the camera module 1100b is described with reference to FIG. 50. According to example embodiments, the same descriptions may be applied to the other camera modules 1100a and 1100c.

Referring to FIG. 50, the camera module 1100b may include a prism 1105, an optical path folding element (OPFE) 1110, an actuator 1130, an image sensing device 1140 and a storage device 1150.

The prism 1105 may include a reflection surface 1107 to change a path of a light L incident on the prism 1105.

In some example embodiments, the prism 1105 may be configured to change the path of the light L incident in a first direction X to the path in a second direction Y perpendicular to the first direction X. In addition, the prism 1105 may rotate the reflection surface 1107 around a center axis 1106 and/or rotate the center axis 1106 in the B direction to align the path of the reflected light along the second direction Y. In addition, the OPFE 1110 may move in a third direction perpendicular to the first direction X and the second direction Y.

In some example embodiments, a rotation angle of the prism 1105 may be smaller than 15 degrees in the positive (+) A direction and greater than 15 degrees in the negative (−) A direction, but example embodiments are not limited thereto.

In some example embodiments, the prism 1105 may rotate within 20 degrees in the positive B direction and the negative B direction.

In some example embodiments, the prism 1105 may move the reflection surface 1107 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may be configured to move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144, and/or a memory 1146. The image sensor 1142 may be configured to capture and/or sense an image using the light provided through the optical lens. The control logic 1144 may control overall operations of the camera module 1100b. For example, the control logic 1144 may provide control signals through control signal line CSLb to control the operation of the camera module 1100b. The image sensor 1142 may include, for example, an image sensor (e.g., the image sensor 600) and/or a pixel (e.g., the pixel PX) according to at least one of the above described example embodiments.

The memory 1146 may store information such as calibration data 1147 for the operation of the camera module 1100b. For example, the calibration data 1147 may include information for generation of image data based on the provided light, such as information on the above-described rotation angle, a focal length, information on an optical axis, and so on. When the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. The storage device 1150 may be disposed outside of (external to) the image sensing device 1140, and the storage device 1150 may be stacked with a sensor chip including the image sensing device 1140. The storage device 1150 may be implemented with an electrically erasable programmable read-only memory (EEPROM), but example embodiments are not limited thereto.

Referring to FIGS. 49 and 50, each of the camera modules 1100a, 1100b, and 1100c may include the actuator 1130. In some example embodiments, the camera modules 1100a, 1100b, and 1100c may include the same or different calibration data 1147 depending on the operations of the actuators 1130.

In some example embodiments, one camera module 1100b may have a folded lens structure included the above-described prism 1105 and the OPFE 1110, and the other camera modules 1100a and 1100b may have a vertical structure without the prism 1105 and the OPFE 1110.

In some example embodiments, one camera module 1100c may be a depth camera configured to measure distance information of an object using an infrared light. In some example embodiments, the application processor 1200 may merge the distance information provided from the camera module (e.g., depth camera) 1100c and image data provided from the other camera modules 1100a and 1100b to generate a three-dimensional depth image.

In some example embodiments, at least two camera modules among the camera modules 1100a, 1100b, and 1100c may have different field of views, for example, through different optical lenses.

In some example embodiments, each of the camera modules 1100a, 1100b, and 1100c may be separated physically from one another. For example, the camera modules 1100a, 1100b, and 1100c may each include a dedicated image sensor 1142.

The application processor 1200 may include an image processing device 1210, a memory controller 1220 and an internal memory 1230. The application processor 1200 may be separated from the camera modules 1100a, 1100b, and 1100c. For example, the application processor 1200 may be implemented as one chip and the camera modules 1100a, 1100b, and 1100c may be implemented as another chip or other chips.

The image processing device 1210 may include a plurality of sub-processors 1212a, 1212b, and 1212c, an image generator 1214 and a camera module controller 1216.

The image data generated by the camera modules 1100a, 1100b, and 1100c may be provided to the sub-processors 1212a, 1212b, and 1212c through distinct image signal lines ISLa, ISLb, and ISLc, respectively. For example, the transfer of the image data may be performed using a camera serial interface (CSI) based on the mobile industry processor interface (MIPI), but example embodiments are not limited thereto.

In some example embodiments, one sub-processor may be assigned commonly to two or more camera modules. In some example embodiments, a multiplexer may be used to transfer the image data selectively from one of the camera modules to the shared sub-processor.

The image data from the sub-processors 1212a, 1212b, and 1212c may be provided to the image generator 1214. The image generator 1214 may generate an output image using the image data from the sub-processors 1212a, 1212b, and 1212c according to image generating information or a mode signal. For example, the image generator 1213 may merge at least a portion of the image data from the camera modules 1100a, 1100b, and 1100c having the different fields of view to generate the output image according to the image generating information or the mode signal. In addition, the image generator 1214 may select, as the output image, one of the image data from the camera modules 1100a, 1100b, and 1100c according to the image generating information or the mode signal.

In some example embodiments, the image generating information may include a zoom factor or a zoom signal. In some example embodiments, the mode signal may be a signal based on a selection of a user.

When the image generating information is the zoom factor and the camera modules 1100a, 1100b, and 1100c have different fields of views, the image generator 1214 may perform different operations depending on the zoom signal. For example, when the zoom signal is a first signal, the image generator 1214 may merge the image data from the different camera modules to generate the output image. When the zoom signal is a second signal different from the first signal, the image generator 1214 may select, as the output image, one of image data from the camera modules 1100a, 1100b, and 1100c.

In some example embodiments, the image generator 1214 may receive the image data of different exposure times from the camera modules 1100a, 1100b, and 1100c. In some example embodiments, the image generator 1214 may perform high dynamic range (HDR) processing with respect to the image data from the camera modules 1100a, 1100b, and 1100c to generate the output image having the increased dynamic range.

The camera module controller 1216 may provide control signals to the camera modules 1100a, 1100b, and 1100c. The control signals generated by the camera module controller 1216 may be provided to the camera modules 1100a, 1100b, and 1100c through the distinct control signal lines CSLa, CSLb, and CSLc, respectively.

In some example embodiments, one of the camera modules 1100a, 1100b, and 1100c may be designated as a master camera according to the image generating information of the mode signal, and the other camera modules may be designated as slave cameras.

The camera module acting as the master camera may be changed according to the zoom factor or an operation mode signal. For example, when the camera module 1100a has a wider field of view than the camera module 1100b and the zoom factor indicates a lower zoom magnification, the camera module 1100b may be designated as the master camera. In contrast, when the zoom factor indicates a higher zoom magnification, the camera module 1100a may be designated as the master camera.

In some example embodiments, the control signals provided from the camera module controller 1216 may include a synch enable signal. For example, when the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In some example embodiments, the control signals provided from the camera module controller 1216 may include information on the operation mode. The camera modules 1100a, 1100b, and 1100c may operate in a first operation mode or a second operation mode based on the information from the camera module controller 1216.

In the first operation mode, the camera modules 1100a, 1100b, and 1100c may generate image signals with a first speed (e.g., a first frame rate) and encode the image signals with a second speed higher than the first speed (e.g., a second frame rate higher than the first frame rate) to transfer the encoded image signals to the application processor 1200. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub-processors 1212a, 1212b, and 1212c may perform the decoding operation and the image generator 1214 may process the decoded image signals.

In the second operation mode, the camera modules 1100a, 1100b, and 1100c may generate image signals with a third speed lower than the first speed (e.g., the third frame rate lower than the first frame rate) to transfer the generated image signals to the application processor 1200. For example, the image signals that are not encoded may be provided to the application processor 1200. The application processor 1200 may process the received image signals or store the receive image signals in the internal memory 1230 or the external memory 1400.

The PMIC 1300 may be configured to provide a power supply voltage to the camera modules 1100a, 1100b, and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the powers respectively corresponding to the camera modules 1100a, 1100b, and 1100c and control power levels, in response to a power control signal PCON from the application processor 1200. The power control signal PCON may include information on the power depending on the operation modes of the camera modules 1100a, 1100b, and 1100c. For example, the operation modes may include a low power mode in which the camera modules 1100a, 1100b, and 1100c operate in low power. The power levels of the camera modules 1100a, 1100b, and 1100c may be the same as or different from one another. In addition, the power levels may be changed dynamically or adaptively.

As described above, the image sensor according to example embodiments may precisely measure the thickness of the color filters included in the image sensor using the non-filter pixels that do not include color filters. Through the precise thickness measurement of the color filters, the performance of the image sensor may be enhanced by the improving the manufacturing process of the image sensor and/or correcting the sensing data of the image sensor.

The example embodiments may be applied to any electronic devices and systems including an image sensor. For example, the example embodiments may be applied to systems such as a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IOT) device, an internet of everything (IoE) device, an e-book, a virtual reality (VR) device, an augmented reality (AR) device, an augmented reality (AR) device, a vehicle navigation device, a video phone, a monitoring system, an auto focusing system, a tracking system, a motion detection system, etc.

The foregoing is illustrative of example embodiments and is not to be construed as limiting thereof. Although a few example embodiments have been described, those skilled in the art will readily appreciate that many modifications are possible in the example embodiments without materially departing from the present inventive concept.

What is claimed is:

1. An image sensor comprising:
a semiconductor substrate including a plurality of pixels;
an insulating film disposed on the semiconductor substrate;
a plurality of color filters disposed on the insulating film; and
a plurality of microlenses disposed on the plurality of color filters,
wherein the plurality of pixels include at least one non-filter pixel having no color filter disposed on the insulating film.

2. The image sensor of claim 1, wherein:
the plurality of pixels include a red pixel having a red filter disposed thereon, a green pixel having a green filter disposed thereon, and a blue pixel having a blue filter disposed thereon, and
the at least one non-filter pixel corresponds to a pixel from which the green filter is omitted.

3. The image sensor of claim 1, wherein the at least one non-filter pixel includes a plurality of non-filter pixels, and the plurality of non-filter pixels are disposed adjacent to one another to form a non-filter pixel group.

4. The image sensor of claim 1, wherein the at least one non-filter pixel includes:
a first non-filter pixel;
a second non-filter pixel arranged adjacent to the first non-filter pixel in a first substantially horizontal direction;
a third non-filter pixel arranged adjacent to the first non-filter pixel in a second substantially horizontal direction substantially perpendicular to the first substantially horizontal direction; and
a fourth non-filter pixel arranged adjacent to the second non-filter pixel in the second substantially horizontal direction and adjacent to the third non-filter pixel in the first substantially horizontal direction.

5. The image sensor of claim 4, wherein:
the plurality of pixels include a red pixel having a red filter disposed thereon, a green pixel having a green filter disposed thereon, and a blue pixel having a blue filter disposed thereon, and
the first non-filter pixel, the second non-filter pixel, the third non-filter pixel, and the fourth non-filter pixel all correspond to a pixel from which the green filter is omitted.

6. The image sensor of claim 1, wherein the plurality of pixels include:
active pixels disposed in an active pixel region corresponding to a central portion of the semiconductor substrate; and
dummy pixels disposed in a dummy pixel region surrounding the active pixel region.

7. The image sensor of claim 6, wherein the at least one non-filter pixel corresponds to a dummy pixel disposed in the dummy pixel region.

8. The image sensor of claim 6, wherein:
a perimeter of the dummy pixel region has a rectangular shape, and the at least one non-filter pixel includes a plurality of corner non-filter pixels disposed at four corners of the rectangular shape.

9. The image sensor of claim 8, wherein the at least one non-filter pixel further includes a plurality of side non-filter pixels disposed at four sides of the rectangular shape.

10. The image sensor of claim 8, wherein the at least one non-filter pixel further includes at least one center non-filter pixel disposed in the active pixel region.

11. The image sensor of claim 1, wherein a microlens is not disposed on the at least one non-filter pixel.

12. The image sensor of claim 1, wherein the at least one non-filter pixel is used as a pixel count marker for identifying positions of the plurality of pixels.

13. The image sensor of claim 1, wherein a surface of the insulating film corresponding to the at least one non-filter pixel is used as a reference surface for measuring a thicknesses of the plurality of color filters.

14. A method of manufacturing an image sensor, comprising:
providing a semiconductor substrate including a plurality of pixels;
forming an insulating film on the semiconductor substrate;
forming a first color filter layer on the insulating film; and
patterning the first color filter layer using a first mask including a plurality of first patterns such that a color filter corresponding to at least one non-filter pixel among the plurality of pixels is not disposed to form a plurality of first color filters corresponding to the plurality of first patterns.

15. The method of claim 14, wherein:
the plurality of pixels include a red pixel having a red filter disposed thereon, a green pixel having a green filter disposed thereon, and a blue pixel having a blue filter disposed thereon, and
the at least one non-filter pixel corresponds to a pixel from which the green filter is omitted.

16. The method of claim 14, further comprising:
after forming the plurality of first color filters, forming a second color filter layer on the insulating film and the plurality of first color filters;
patterning the third color filter layer using a second mask including a plurality of second patterns to form a plurality of second color filters corresponding to the plurality of second patterns;
after forming the plurality of second color filters, forming a third color filter layer on the insulating film, the plurality of first color filters, and the plurality of second color filters; and
patterning the third color filter layer using a third mask including a plurality of third patterns to form a plurality of third color filters corresponding to the plurality of third patterns.

17. The method of claim 16, wherein:
the plurality of first color filters correspond to green pixels, the plurality of second color filters correspond to blue pixels, and the plurality of third color filters correspond to red pixels, and
the at least one non-filter pixel corresponds to a pixel from which the green filter is omitted.

18. The method of claim 17, further comprising:
measuring thicknesses of the plurality of color filters using a surface of the insulating film corresponding to the at least one non-filter pixel as a reference surface.

19. The method of claim 16, further comprising:
measuring a thickness of the plurality of first color filters after forming the plurality of first color filters and before forming the second color filter layer;
measuring thicknesses of the plurality of first color filters and the plurality of second color filters after forming the plurality of second color filters and before forming the third color filter layer; and
measuring thicknesses of the plurality of first color filters, the plurality of second color filters, and the plurality of third color filters after forming the plurality of third color filters.

20. An image sensor comprising:
a semiconductor substrate including a plurality of green pixels, a plurality of blue pixels, and a plurality of red pixels;
an insulating film disposed on the semiconductor substrate;
a plurality of green filters, a plurality of blue filters, and a plurality of red filters disposed on the insulating film; and
a plurality of microlenses disposed on the plurality of green filters, the plurality of blue filters, and the plurality of red filters,
wherein the plurality of green pixels include at least one non-filter pixel having no green filter disposed on the insulating film.
